(19) United States
(12) Patent Application Publication
(10) Pub. No.: US 2025/0096143 A1
(43) Pub. Date: Mar. 20, 2025

(54) MICROELECTRONIC ASSEMBLY WITH BRIDGE DIE AND SELECTIVE METALLIZATION LAYERS

(71) Applicant: Intel Corporation, Santa Clara, CA (US)

(72) Inventors: Jeremy Ecton, Gilbert, AZ (US); Brandon C. Marin, Gilbert, AZ (US); Tarek A. Ibrahim, Mesa, AZ (US); Srinivas V. Pietambaram, Chandler, AZ (US); Gang Duan, Chandler, AZ (US)

(73) Assignee: Intel Corporation, Santa Clara, CA (US)

(21) Appl. No.: 18/470,668

(22) Filed: Sep. 20, 2023

(51) Int. Cl. H01L 23/538; H01L 21/48

(52) U.S. Cl. CPC H01L 23/5381; H01L 21/4857; H01L 23/5383; H01L 23/5386

(57) ABSTRACT

A microelectronic assembly includes a bridge die embedded in a substrate. The substrate includes a doped dielectric material in a layer or region directly below the bridge die, and in a layer near an upper face of the bridge die. A cavity is formed in the upper layer of the doped dielectric material for embedding the bridge die, exposing the lower layer of the doped dielectric material. After cavity formation, a selective metallization of the lower and upper layers of the doped dielectric material is performed, providing well-aligned metal layers in the region of the bridge die and the region around the bridge die.

### BACKGROUND

Integrated circuit (IC) devices (e.g., dies) can be coupled together in a multi-die IC package to integrate features or functionality and to facilitate connections to other components, such as package substrates. IC packages may include an embedded multi-die interconnect bridge (EMIB) for coupling two or more IC dies.

### BRIEF DESCRIPTION OF THE DRAWINGS

Embodiments will be readily understood by the following detailed description in conjunction with the accompanying drawings. To facilitate this description, like reference numerals designate like structural elements. Embodiments are illustrated by way of example, not by way of limitation, in the figures of the accompanying drawings.

FIG. 1 is a side, cross-sectional view of an example microelectronic assembly, in accordance with various embodiments.

FIG. 2 is a flow diagram of an example process for manufacturing a microelectronic assembly, in accordance with various embodiments.

FIGS. 3A-3M are side, cross-sectional views of various stages in an example process for manufacturing the microelectronic assembly of FIG. 1, in accordance with various embodiments.

FIG. 4A and 4B illustrate alternate configurations of conductive structures in doped dielectric layers, in accordance with various embodiments.

FIG. 5 is a top view of a wafer and dies that may be included in a microelectronic assembly, in accordance with any of the embodiments disclosed herein.

FIG. 6 is a cross-sectional side view of an IC device that may be included in a microelectronic assembly, in accordance with any of the embodiments disclosed herein.

FIG. 7 is a cross-sectional side view of an IC device assembly that may include a microelectronic assembly, in accordance with any of the embodiments disclosed herein.

FIG. 8 is a block diagram of an example electrical device that may include a microelectronic assembly, in accordance with any of the embodiments disclosed herein.

### DETAILED DESCRIPTION

Communicating large numbers of signals between two or more dies in a multi-die IC package is challenging due to the increasingly small size of such dies and increased use of stacking dies. As transistor density increases with each new silicon node, yielding large, monolithic dies has become increasingly difficult, leading to an industry push toward die disaggregation. Multi-die IC packaging typically requires increased die segregation, additional power delivery requirements, and stricter routing and alignment tolerances throughout the package. The greater number of embedded dies and smaller size of embedded dies (i.e., bridge dies, passives, etc.) vastly increases manufacturing complexity as well as routing complexity as power signals must be routed around embedded dies. Various ones of the embodiments disclosed herein may help reduce the cost and complexity associated with assembling multi-die IC packages relative to conventional approaches by incorporating double-sided embedded dies with through-silicon vias (TSVs) that enable power signals to be routed through the embedded dies.

To produce packages with embedded dies, a substrate is built up with multiple metal routing layers formed in dielectric. After forming the metal layers, a cavity is created within the substrate, exposing contacts for the embedded die. The die is placed into the cavity and bonded to the substrate, with conductive structures on the embedded die being coupled to the exposed contacts in the cavity. The cavity is filled in with additional dielectric, and additional metal routing is formed over the embedded die, providing electrical connections to and from the embedded die. One or more dies are coupled to the embedded die and to the metal routing within the substrate.

Because the contacts under the embedded die are formed relatively early in the process, and the contacts at the top of the substrate are formed relatively late in the process, there may be misalignment between contacts under the embedded die and contacts in other regions, e.g., contacts over the embedded die, and contacts to routing layers on either side of the embedded die. This can lead to challenges when aligning and placing dies over the substrate with the embedded die.

Disclosed herein is a fabrication process that improves alignment across contacts on different portions of the substrate (e.g., to improve alignment and positioning between contacts over the through-substrate routing layers and contacts over the embedded die), and microelectronic assemblies produced using this fabrication process. While it is desirable to pattern the contacts under the embedded die relatively later in the fabrication (e.g., after etching the cavity for the embedded die), it is difficult to perform traditional lithographic pattern in a cavity. Therefore, a selective metallization process using a doped dielectric layer is used to pattern the metal layer below the cavity after the cavity is formed. A similar layer of doped dielectric may also be provided at an upper layer of the substrate in the region surrounding the cavity. Thus, an upper layer of the substrate routing layers may be patterned simultaneously with the layer at the bottom of the cavity. This provides improved alignment of these layers. When a bridge die is embedded in the cavity, its upper conductive structures may in turn be better aligned with the conductive contacts around the cavity than in previous fabrication methods, which improves the positioning and alignment of contacts across the top of the substrate.

In the following detailed description, reference is made to the accompanying drawings that form a part hereof wherein like numerals designate like parts throughout, and in which is shown, by way of illustration, embodiments that may be practiced. It is to be understood that other embodiments may be utilized, and structural or logical changes may be made without departing from the scope of the present disclosure. Therefore, the following detailed description is not to be taken in a limiting sense. The accompanying drawings are not necessarily drawn to scale. Although many of the drawings illustrate rectilinear structures with flat walls and right-angle corners, this is simply for ease of illustration, and actual devices made using these techniques will exhibit rounded corners, surface roughness, and other features. It is to be understood that such schematic illustrations may not reflect real-life process limitations which may cause the features to not look so “ideal” when any of the structures described herein are examined using, e.g., images of suitable characterization tools such as scanning electron microscopy (SEM) images, transmission electron microscope (TEM) images, or non-contact profilometer. In such images of real structures, possible processing and/or surface defects could also be visible, e.g., surface roughness, curvature or profile deviation, pit or scratches, not-perfectly straight edges of materials, tapered vias or other openings, inadvertent rounding of corners or variations in thicknesses of different material layers, occasional screw, edge, or combination dislocations within the crystalline region(s), and/or occasional dislocation defects of single atoms or clusters of atoms. There may be other defects not listed here but that are common within the field of device fabrication and/or packaging.

Various operations may be described as multiple discrete actions or operations in turn, in a manner that is most helpful in understanding the claimed subject matter. However, the order of description should not be construed as to imply that these operations are necessarily order dependent. In particular, these operations may not be performed in the order of presentation. Operations described may be performed in a different order from the described embodiment. Various additional operations may be performed, and/or described operations may be omitted in additional embodiments.

For the purposes of the present disclosure, the phrase “A and/or B” means (A), (B), or (A and B). For the purposes of the present disclosure, the phrase “A, B, and/or C” means (A), (B), (C), (A and B), (A and C), (B and C), or (A, B, and C).

The description uses the phrases “in an embodiment” or “in embodiments,” which may each refer to one or more of the same or different embodiments. Furthermore, the terms “comprising,” “including,” “having,” and the like, as used with respect to embodiments of the present disclosure, are synonymous. As used herein, a “package” and an “IC package” are synonymous, as are a “die” and an “IC die.” The terms “top” and “bottom” may be used herein to explain various features of the drawings, but these terms are simply for ease of discussion, and do not imply a desired or required orientation. As used herein, the term “insulating” means “electrically insulating,” unless otherwise specified. Throughout the specification, and in the claims, the term “coupled” means a direct or indirect connection, such as a direct electrical, mechanical, or magnetic connection between the things that are connected or an indirect connection, through one or more passive or active intermediary devices. The meaning of “a,” “an,” and “the” include plural references. The meaning of “in” includes “in” and “on.” Unless otherwise specified the use of the ordinal adjectives “first,” “second,” and “third,” etc., to describe a common object, merely indicate that different instances of like objects are being referred to, and are not intended to imply that the objects so described must be in a given sequence, either temporally, spatially, in ranking or in any other manner. The term “circuit” means one or more passive and/or active components that are arranged to cooperate with one another to provide a desired function. The terms “substantially,” “close,” “approximately,” “near,” and “about,” generally refer to being within +/−20% of a target value (e.g., within +/−5 or 10% of a target value) based on the context of a particular value as described herein or as known in the art. Similarly, terms indicating orientation of various elements, e.g., “coplanar,” “perpendicular,” “orthogonal,” “parallel,” or any other angle between the elements, generally refer to being within +/−5-20% of a target value based on the context of a particular value as described herein or as known in the art.

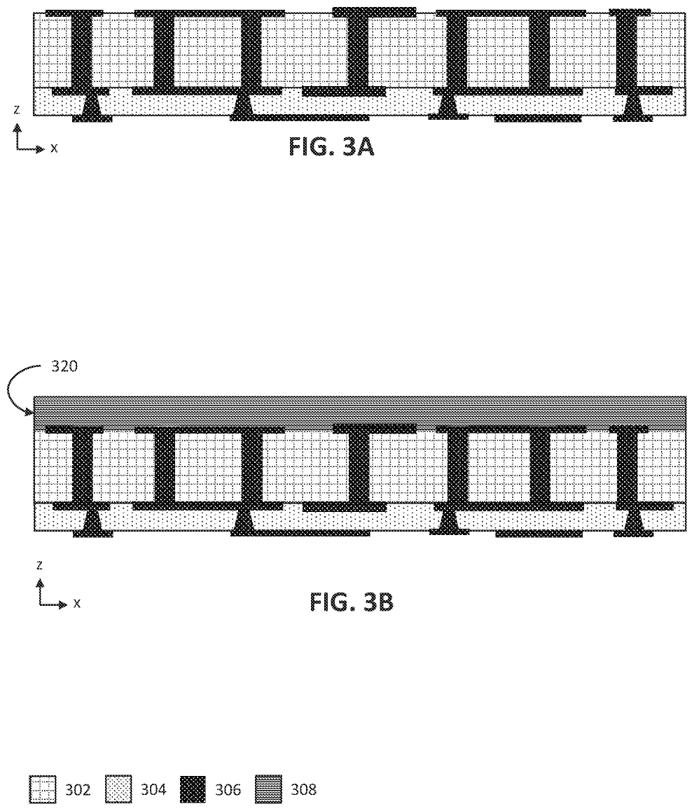

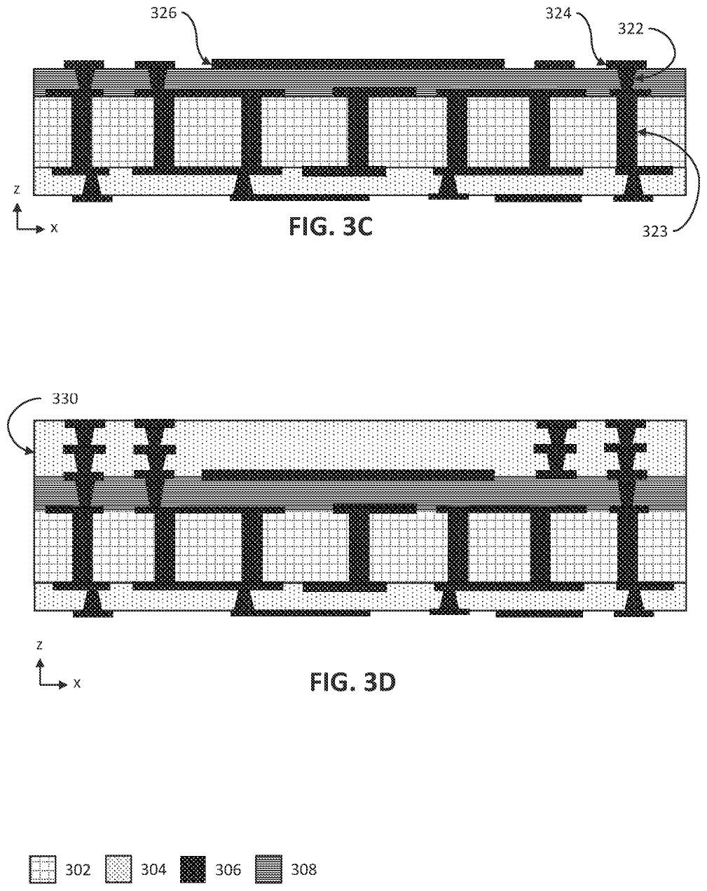

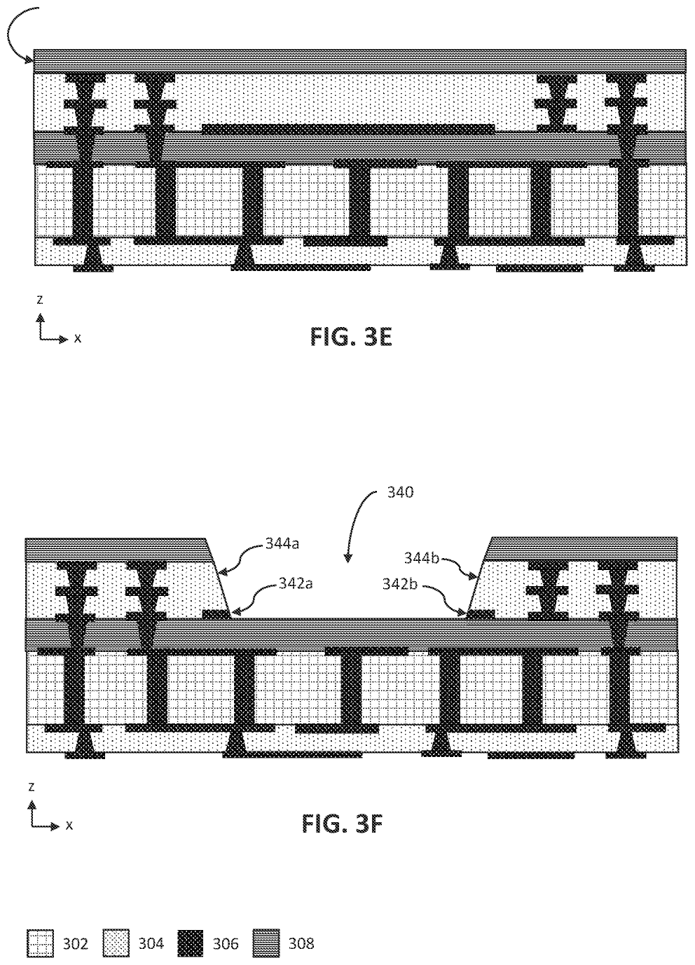

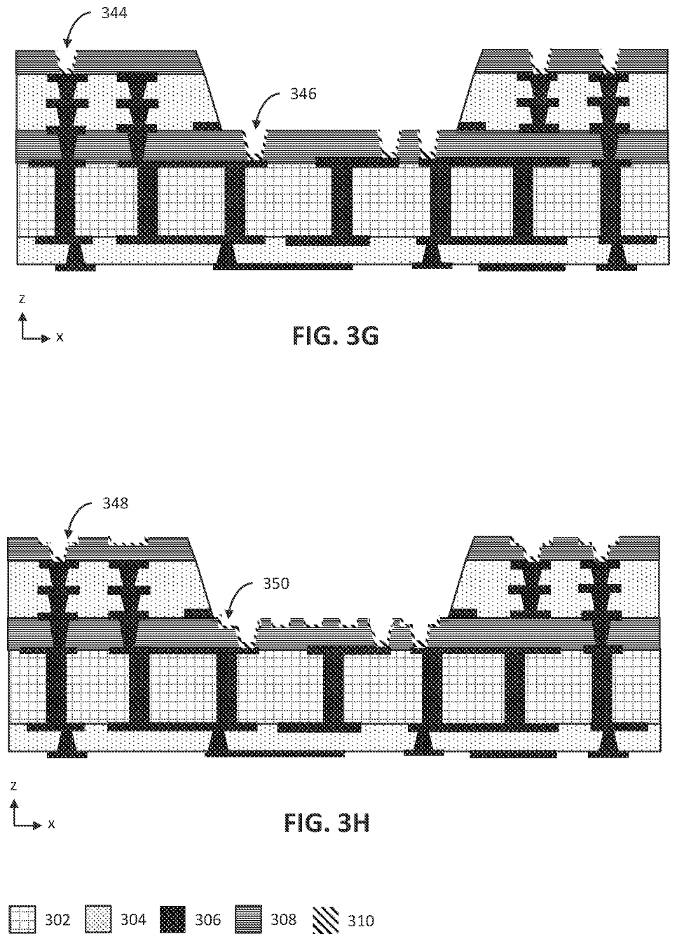

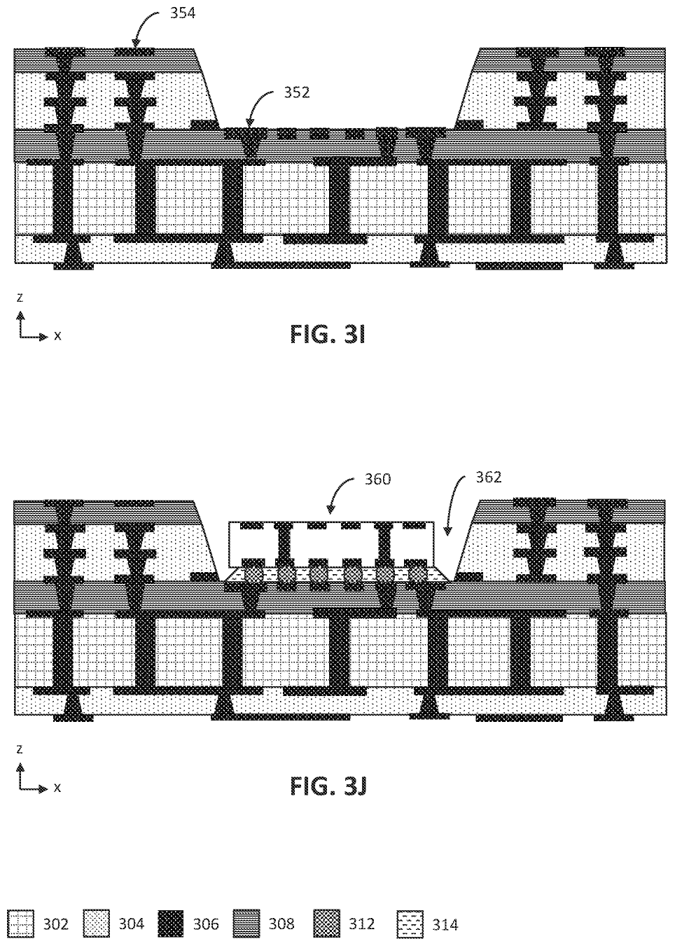

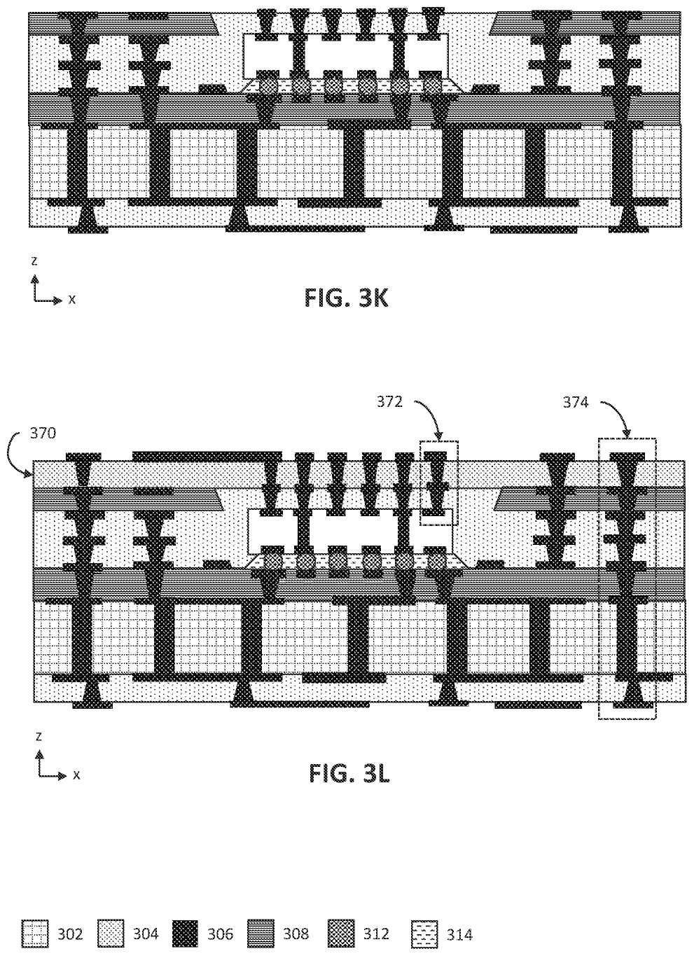

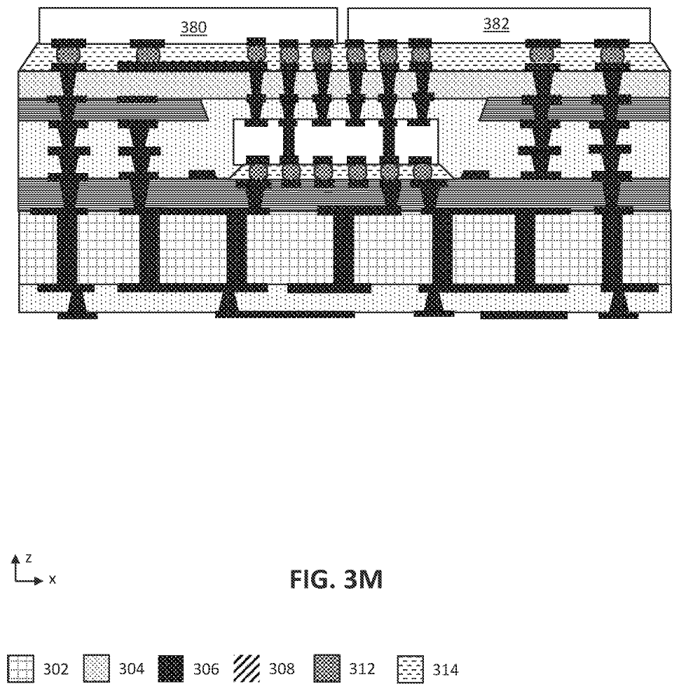

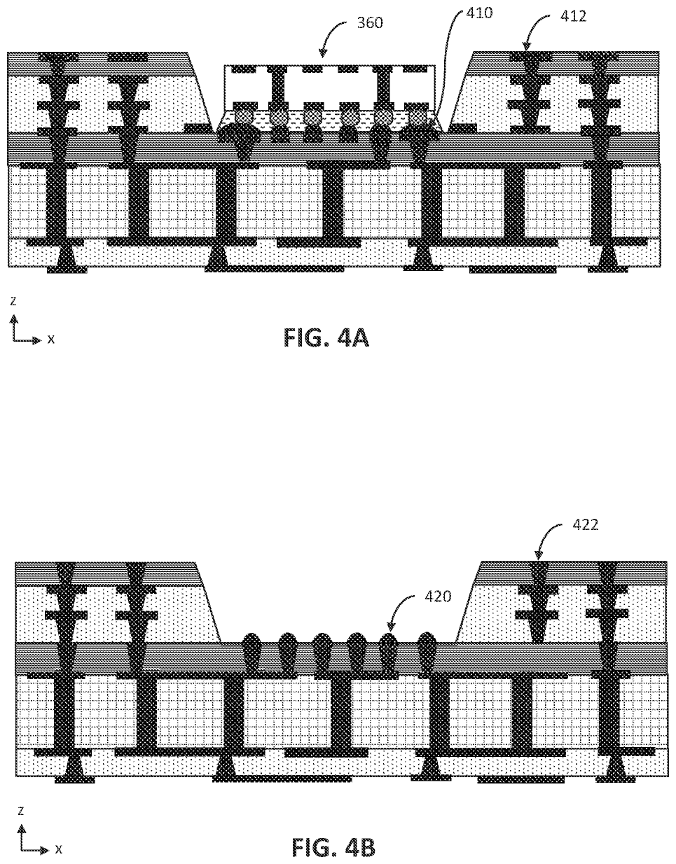

When used to describe a range of dimensions, the phrase “between X and Y” represents a range that includes X and Y. For convenience, the phrase “FIG. 3” may be used to refer to the collection of drawings of FIGS. 3A-3M, the phrase “FIG. 4” may be used to refer to the collection of drawings of FIGS. 4A-4B, etc. Although certain elements may be referred to in the singular herein, such elements may include multiple sub-elements. For example, “an insulating material” may include one or more insulating materials.

### Example Assembly with Doped Dielectric Layers and Embedded Bridge Die

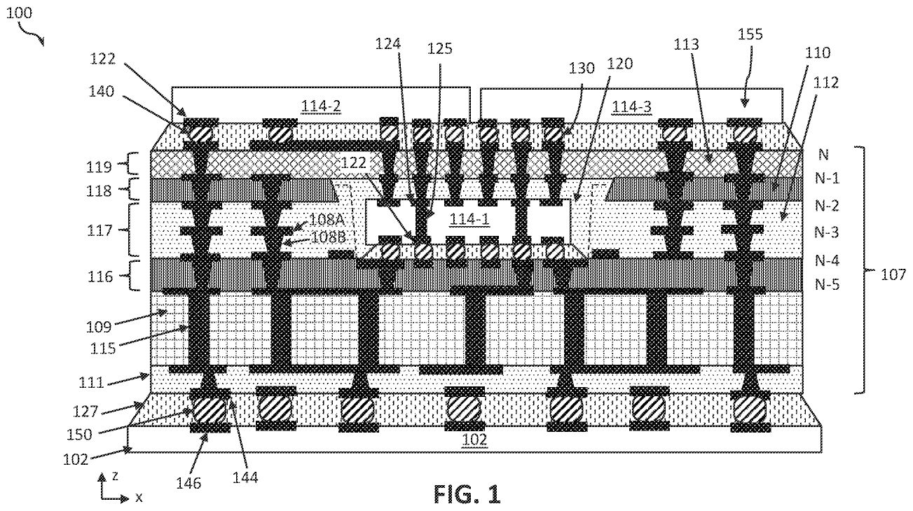

FIG. 1 is a side, cross-sectional view of an example microelectronic assembly, in accordance with various embodiments. The microelectronic assembly 100 may include a substrate 107 with a double-sided bridge die 114-1 that is formed within a cavity 120 in the substrate 107, as illustrated in the process steps shown in FIG. 3. The substrate 107 may include a dielectric material 112, a doped dielectric material 110, and a conductive material 108 (e.g., lines/traces/pads/contacts 108A and vias 108B, as shown), with the conductive material 108 arranged in the dielectric material 112 and doped dielectric material 110 to provide conductive pathways through the substrate 107.

The substrate 107 includes layers 116, 117, 118, and 119. The layer 116 includes the doped dielectric material 110 and conductive structures formed therein. The layer 116 is below the bridge die 114-1. The layer 117 is over the layer 116 and includes the dielectric material 112, the bridge die 114-1, and conductive structures formed within the dielectric material 112 and the bridge die 114-1. Some of the conductive structures in the dielectric material 112 in the layer 117 are portions of through-substrate vias, which extend substantially vertically (i.e., in the z-direction in the coordinate system shown) through at least the layers 116-119 and are conductively coupled to the die 114-2 or 114-3. For example, the through-substrate via 155 extends substantially vertically between the die 114-3 and the package substrate 102. The die 114-1 may be surrounded by a dielectric material 112 of the substrate 107.

The layer 118 includes both the dielectric material 112 and the doped dielectric material 110 in different portions. In particular, the dielectric material 112 is in a portion over the bridge die 114-1, and the doped dielectric material 110 is in an area outside the bridge die 114-1. For example, the doped dielectric material 110 is in a region that includes through-substrate vias, e.g., the through-substrate via 155 extends through the doped dielectric material 110 in the layer 118.

The layer 119 includes a dielectric material 113 and conductive structures formed within the dielectric material. In the example of FIG. 1, a different pattern from the materials 110 and 112 is used to illustrate the dielectric material 113 in the layer 119, which may indicate that the dielectric material 113 is a different material from the dielectric material 112 or the doped dielectric material 110. In other examples, dielectric material 113 may be the dielectric material 112 or dielectric material 110. In addition, conductive structures are in layer 119; these conductive structures include portions of through-substrate vias (e.g., a portion of the through-substrate via 155) and vias that are conductively coupled to the bridge die 114-1. In some embodiments, the layer 119 may be omitted; in such embodiments, the layer 118 with the doped dielectric material 110 is a top or uppermost layer of the substrate 107, and the dies 114-2 and 114-3 are attached to the layer 118 with the doped dielectric material 110 (e.g., with solder bonds).

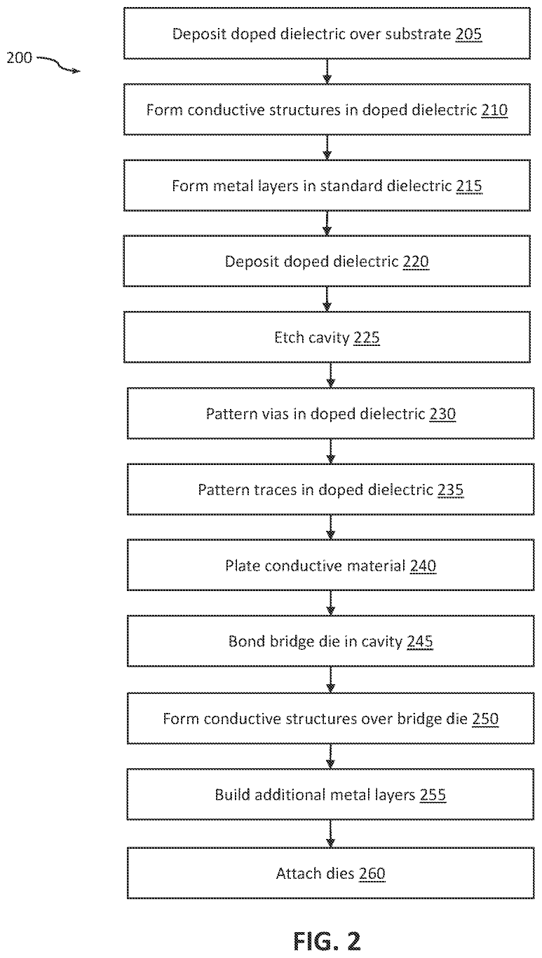

The doped dielectric material 110 enables patterning of the conductive structures in the portion of the layer 116 below the bridge die 114-1 after formation of the cavity 120. The conductive structures in the portion of the layer 116 below the bridge die 114-1 are patterned and formed simultaneously with the conductive structures in the doped dielectric material 110 in the layer 118, as illustrated in FIGS. 2 and 3.

The die 114-1 may include a bottom surface with first conductive contacts 122, an opposing top surface with second conductive contacts 124, and TSVs 125 coupling respective first and second conductive contacts 122, 124. In some embodiments, a pitch of the first conductive contacts 122 on the first die 114-1 maybe between 25 microns and 250 microns. As used herein, pitch is measured center-to-center (e.g., from a center of a conductive contact to a center of an adjacent conductive contact). In some embodiments, a pitch of the second conductive contacts 124 on the first die 114-1 maybe between 25 microns and 100 microns.

The dies 114-2, 114-3 may include a set of conductive contacts 122 on the bottom surface of the die (e.g., the surface facing towards an upper surface of the substrate 107). The dies 114-1, 114-2, and 114-3 may include other conductive pathways (e.g., including lines and vias) and/or to other circuitry (not shown) coupled to the respective conductive contacts (e.g., conductive contacts 122, 124) on the surfaces of the dies 114. As used herein, the terms “die,” “microelectronic component,” and similar variations may be used interchangeably. As used herein, the terms “interconnect component,” “bridge die,” and similar variations may be used interchangeably. The bridge die 114-1 may be electrically coupled to dies 114-2, 114-3 by die-to-die (DTD) interconnects 130. The DTD interconnects 130 are over the upper surface of the substrate 107. In particular, conductive contacts 124 on a top surface of the die 114-1 may be coupled to conductive contacts 122 on a bottom surface of dies 114-2, 114-3 by conductive vias 108B through the dielectric material 112B and DTD interconnects 130.

As used herein, a “conductive contact” may refer to a portion of conductive material (e.g., metal) serving as an electrical interface between different components (e.g., part of a conductive interconnect); conductive contacts may be recessed in, flush with, or extending away (e.g., having a pillar shape) from a surface of a component, and may take any suitable form (e.g., a conductive pad or socket, or portion of a conductive line or via). In a general sense, an “interconnect” refers to any element that provides a physical connection between two other elements. For example, an electrical interconnect provides electrical connectivity between two electrical components, facilitating communication of electrical signals between them; an optical interconnect provides optical connectivity between two optical components, facilitating communication of optical signals between them. As used herein, both electrical interconnects and optical interconnects are comprised in the term “interconnect.” The nature of the interconnect being described is to be understood herein with reference to the signal medium associated therewith. Thus, when used with reference to an electronic device, such as an IC that operates using electrical signals, the term “interconnect” describes any element formed of an electrically conductive material for providing electrical connectivity to one or more elements associated with the IC or/and between various such elements. In such cases, the term “interconnect” may refer to both conductive traces (also sometimes referred to as “metal traces,” “lines,” “metal lines,” “wires,” “metal wires,” “trenches,” or “metal trenches”) and conductive vias (also sometimes referred to as “vias” or “metal vias”). Sometimes, electrically conductive traces and vias may be referred to as “conductive traces” and “conductive vias”, respectively, to highlight the fact that these elements include electrically conductive materials such as metals. Likewise, when used with reference to a device that operates on optical signals as well, such as a photonic IC (PIC), “interconnect” may also describe any element formed of a material that is optically conductive for providing optical connectivity to one or more elements associated with the PIC. In such cases, the term “interconnect” may refer to optical waveguides (e.g., structures that guide and confine light waves), including optical fiber, optical splitters, optical combiners, optical couplers, and optical vias.

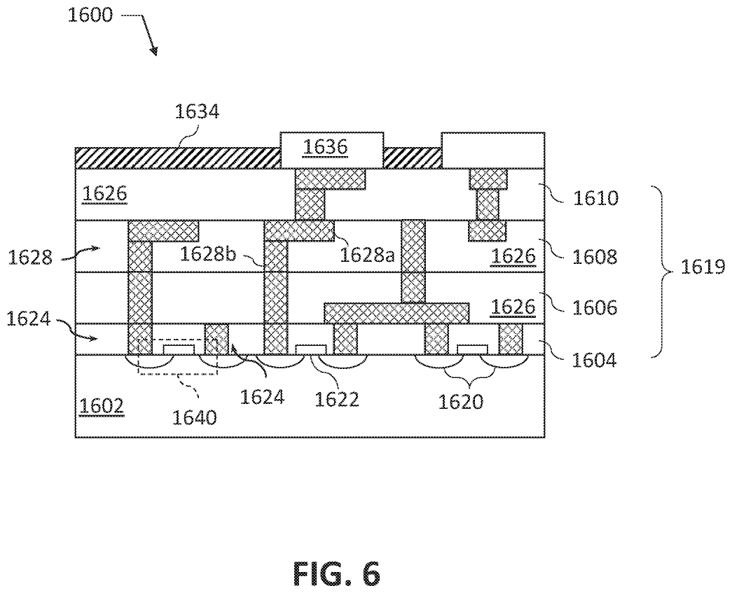

The die 114 disclosed herein may include an insulating material (e.g., a dielectric material formed in multiple layers, as known in the art) and multiple conductive pathways formed through the insulating material. In some embodiments, the insulating material of a die 114 may include a dielectric material, such as silicon dioxide, silicon nitride, oxynitride, polyimide materials, glass reinforced epoxy matrix materials, or a low-k or ultra low-k dielectric (e.g., carbon-doped dielectrics, fluorine-doped dielectrics, porous dielectrics, organic polymeric dielectrics, photo-imageable dielectrics, and/or benzocyclobutene-based polymers). In some embodiments, the insulating material of a die 114 may include a semiconductor material, such as silicon, germanium, or a III-V material (e.g., gallium nitride), and one or more additional materials. For example, an insulating material may include silicon oxide or silicon nitride. The conductive pathways in a die 114 may include conductive traces and/or conductive vias, and may connect any of the conductive contacts in the die 114 in any suitable manner (e.g., connecting multiple conductive contacts on a same surface or on different surfaces of the die 114). Example structures that may be included in the dies 114 disclosed herein are discussed below with reference to FIG. 6. The conductive pathways in the dies 114 may be bordered by liner materials, such as adhesion liners and/or barrier liners, as suitable. In some embodiments, the die 114 is a wafer. In some embodiments, the die 114 is a monolithic silicon, a fan-out or fan-in package die, or a die stack (e.g., wafer stacked, die stacked, or multi-layer die stacked).

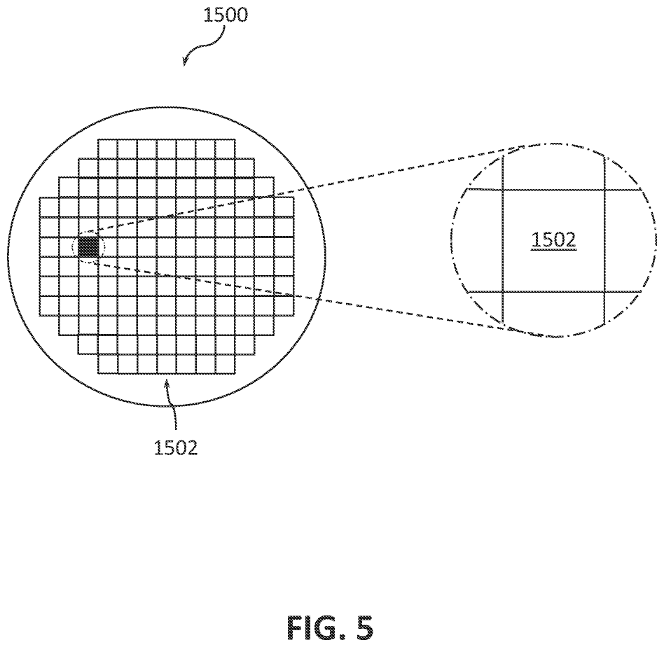

In some embodiments, the die 114 may include conductive pathways to route power, ground, and/or signals to/from other dies 114 included in the microelectronic assembly 100. For example, the die 114-1 may include TSVs 125, including a conductive material via, such as a metal via, isolated from the surrounding silicon or other semiconductor material by a barrier oxide), or other conductive pathways through which power, ground, and/or signals may be transmitted between a package substrate 102 and one or more dies 114 “on top” of the die 114-1 (e.g., in the embodiment of FIG. 1, the dies 114-2 and/or 114-3). In some embodiments, the die 114-1 may not route power and/or ground to the dies 114-2 and 114-3; instead, the dies 114-2, 114-3 may couple directly to power and/or ground lines in the package substrate 102 by substrate-to-package substrate (STPS) interconnects 150, conductive pathways 108 in the substrate 107, and die-to-substrate (DTS) interconnects 140. In some embodiments, the die 114-1 may be thicker than the dies 114-2, 114-3. In some embodiments, the die 114-1 may be a memory device (e.g., as described below with reference to the die 1502 of FIG. 5), or a high frequency serializer and deserializer (SerDes), such as a Peripheral Component Interconnect (PCI) express. In some embodiments, the die 114-1 may be a processing die, a radio frequency chip, a power converter, a network processor, a workload accelerator, a voltage regulator die, or a security encryptor. In some embodiments, the die 114-2 and/or the die 114-3 may be a processing die, a radio frequency chip, a power converter, a network processor, a workload accelerator, a voltage regulator die, or a security encryptor.

The dielectric material of the substrate 107 may be formed in layers, such as the layers 116, 117, 118, and 119 described above. In some embodiments, the dielectric material 112 and/or 113 may include an organic material, such as an organic build-up film. In some embodiments, the dielectric material 112 and/or 113 may include a ceramic, an epoxy film having filler particles therein, glass, an inorganic material, or combinations of organic and inorganic materials, for example. The doped dielectric material 110 further includes a dopant, such as palladium, which can act as a catalyst for forming conductive structures of the conductive material 108. The conductive material 108 may include a metal (e.g., copper). In some embodiments, the substrate 107 may include layers of dielectric materials and conductive material 108, with lines/traces/pads/contacts (e.g., 108A) of conductive material 108 in one layer electrically coupled to lines/traces/pads/contacts (e.g., 108A) of conductive material 108 in an adjacent layer by vias (e.g., 108B) of the conductive material 108 extending through the dielectric material 110, 112, or 113. Conductive elements 108A may be referred to herein as “conductive lines,” “conductive traces,” “conductive pads,” or “conductive contacts.” A substrate 107 including such layers may be formed using a printed circuit board (PCB) fabrication technique, for example.

As noted above, the layers 117 and 118 may include a cavity 120, and the bridge die 114-1 may be at least partially nested in the cavity 120. In some embodiments, a cavity 120 is tapered, narrowing towards a bottom surface of the cavity 120. A cavity 120 may be indicated by a seam near the cavity boundary indicated in dashed lines. In some embodiments, the bridge die 114-1 may be partially nested in the cavity 120, such that a top surface of the bridge die 114-1 may extend above a top surface of the layer 117 or above a top surface of the layer 118. In cases where the bridge die 114-1 is fully nested in a cavity 120, a top surface of the bridge die 114-1 is planar with or below a top surface of the layer 117 or the layer 118.

The substrate 107 may include N layers of conductive material 108, where N is an integer greater than or equal to one; in the accompanying drawings, the layers are labeled in descending order from the upper surface of the substrate 107 (e.g., layer N, layer N-1, layer N-2, etc.). In particular, as shown in FIG. 1, a substrate 107 may include six metal layers (e.g., N, N-1, N-2, N-3, N-4, and N-5). The N metal layer may include conductive contacts 108A at a top surface of the substrate 107 that are coupled to conductive contacts 122 at bottom surfaces of the die 114-2, 114-3 by DTS interconnects 140. The N-3 metal layer may include conductive traces 108A having a top surface, an opposing bottom surface, and lateral surfaces extending between the top and bottom surfaces of the conductive traces 108A.

Although a particular number and arrangement of layers of dielectric material 112/conductive material 108 are shown in various ones of the accompanying figures, these particular numbers and arrangements are simply illustrative, and any desired number and arrangement of dielectric material 112/conductive material 108 may be used. Further, although a particular number of layers are shown in the substrate 107 (e.g., six layers), these layers may represent only a portion of the substrate 107, for example, fewer layers may be present, or further layers may be present (e.g., layers N-6, N-7, etc.). As shown in FIG. 1, the substrate 107 may further include a core 109 with through core vias 115 and one or more further layers 111 may be present below the core 109. The substrate 107 (e.g., the lower layer(s) 111) may be coupled to a package substrate 102 by interconnects 150. In some embodiments, a substrate 107 may not include a core 109 and/or further layers 111. The core 109 may be formed of any suitable material, including glass, a fiber-reinforced epoxy, an organic dielectric material, such as an epoxy, or a phenolic resin or polyimide resin reinforced with glass, aramid, or nylon.

The substrate 107 (e.g., further layers 111) may be coupled to a package substrate 102 by STPS interconnects 150. In particular, the top surface of the package substrate 102 may include a set of conductive contacts 146. Conductive contacts 144 on the bottom surface of the substrate 107 may be electrically and mechanically coupled to the conductive contacts 146 on the top surface of the package substrate 102 by the STPS interconnects 150. The package substrate 102 may include an insulating material (e.g., a dielectric material formed in multiple layers, as known in the art) and one or more conductive pathways to route power, ground, and signals through the dielectric material (e.g., including conductive traces and/or conductive vias, as shown). In some embodiments, the insulating material of the package substrate 102 may be a dielectric material, such as an organic dielectric material, a fire-retardant grade 4 material (FR-4), BT resin, polyimide materials, glass reinforced epoxy matrix materials, organic dielectrics with inorganic fillers or low-k and ultra low-k dielectric (e.g., carbon-doped dielectrics, fluorine-doped dielectrics, porous dielectrics, and organic polymeric dielectrics). In particular, when the package substrate 102 is formed using standard PCB processes, the package substrate 102 may include FR-4, and the conductive pathways in the package substrate 102 may be formed by patterned sheets of copper separated by build-up layers of the FR-4. The conductive pathways in the package substrate 102 may be bordered by liner materials, such as adhesion liners and/or barrier liners, as suitable. In some embodiments, the package substrate 102 may be formed using a lithographically defined via packaging process. In some embodiments, the package substrate 102 may be manufactured using standard organic package manufacturing processes, and thus the package substrate 102 may take the form of an organic package. In some embodiments, the package substrate 102 may be a set of redistribution layers formed on a panel carrier by laminating or spinning on a dielectric material, and creating conductive vias and lines by laser drilling and plating. In some embodiments, the package substrate 102 may be formed on a removable carrier using any suitable technique, such as a redistribution layer technique. Any method known in the art for fabrication of the package substrate 102 may be used, and for the sake of brevity, such methods will not be discussed in further detail herein.

In some embodiments, the package substrate 102 may be a lower density medium and the die 114 may be a higher density medium or have an area with a higher density medium. As used herein, the term “lower density” and “higher density” are relative terms indicating that the conductive pathways (e.g., including conductive interconnects, conductive lines, and conductive vias) in a lower density medium are larger and/or have a greater pitch than the conductive pathways in a higher density medium. In some embodiments, a higher density medium may be manufactured using a modified semi-additive process or a semi-additive build-up process with advanced lithography (with small vertical interconnect features formed by advanced laser or lithography processes), while a lower density medium may be a PCB manufactured using a standard PCB process (e.g., a standard subtractive process using etch chemistry to remove areas of unwanted copper, and with coarse vertical interconnect features formed by a standard laser process). In other embodiments, the higher density medium may be manufactured using semiconductor fabrication process, such as a single damascene process or a dual damascene process. In some embodiments, additional dies may be disposed on the top surface of the dies 114-2, 114-3. In some embodiments, additional components may be disposed on the top surface of the dies 114-2, 114-3. Additional passive components, such as surface-mount resistors, capacitors, and/or inductors, may be disposed on the top surface or the bottom surface of the package substrate 102, or embedded in the package substrate 102.

The microelectronic assembly 100 of FIG. 1 may also include an underfill material 127. In some embodiments, the underfill material 127 may extend between the substrate 107 and the package substrate 102 around the associated STPS interconnects 150. In some embodiments, the underfill material 127 may extend between different ones of the top level dies 114-2, 114-3 and the top surface of the substrate 107 around the associated DTS interconnects 140 and between the bridge die 114-1 and the top level dies 114-2, 114-3 around the DTD interconnects 130. In addition, the underfill material 127 may extend between the die 114-1 and a portion of the top surface of the layer 116 around solder interconnects coupling conductive structures at a lower face of the die 114-1 to conductive contacts at the top of the layer 116. The underfill material 127 may be an insulating material, such as an appropriate epoxy material. In some embodiments, the underfill material 127 may include a capillary underfill, non-conductive film (NCF), or molded underfill. In some embodiments, the underfill material 127 may include an epoxy flux that assists with soldering the multi-layer die subassembly 104 to the package substrate 102 when forming the STPS interconnects 150, and then polymerizes and encapsulates the STPS interconnects 150. The underfill material 127 may be selected to have a coefficient of thermal expansion (CTE) that may mitigate or minimize the stress between the substrate 107 and the package substrate 102 arising from uneven thermal expansion in the microelectronic assembly 100. In some embodiments, the CTE of the underfill material 127 may have a value that is intermediate to the CTE of the package substrate 102 (e.g., the CTE of the dielectric material of the package substrate 102) and a CTE of the dies 114 and/or dielectric material 112 of the substrate 107.

The STPS interconnects 150 disclosed herein may take any suitable form. In some embodiments, a set of STPS interconnects 150 may include solder (e.g., solder bumps or balls that are subject to a thermal reflow to form the STPS interconnects 150), for example, as shown in FIG. 1, the STPS interconnects 150 may include solder between a conductive contacts 144 on a bottom surface of the substrate 107 and a conductive contact 146 on a top surface of the package substrate 102. In some embodiments, a set of STPS interconnects 150 may include an anisotropic conductive material, such as an anisotropic conductive film or an anisotropic conductive paste. An anisotropic conductive material may include conductive materials dispersed in a non-conductive material.

The DTD interconnects 130 disclosed herein may take any suitable form. The DTD interconnects 130 may have a finer pitch than the STPS interconnects 150 in a microelectronic assembly. In some embodiments, the dies 114 on either side of a set of DTD interconnects 130 may be unpackaged dies, and/or the DTD interconnects 130 may include small conductive bumps (e.g., copper bumps). The DTD interconnects 130 may have too fine a pitch to couple to the package substrate 102 directly (e.g., too fine to serve as DTS interconnects 140 or STPS interconnects 150). In some embodiments, a set of DTD interconnects 130 may include solder. In some embodiments, a set of DTD interconnects 130 may include an anisotropic conductive material, such as any of the materials discussed above. In some embodiments, the DTD interconnects 130 may be used as data transfer lanes, while the STPS interconnects 150 may be used for power and ground lines, among others. In some embodiments, some or all of the DTD interconnects 130 in a microelectronic assembly 100 may be metal-to-metal interconnects (e.g., copper-to-copper interconnects, or plated interconnects). In such embodiments, the DTD interconnect 130 may be bonded together (e.g., under elevated pressure and/or temperature) without the use of intervening solder or an anisotropic conductive material. Any of the conductive contacts disclosed herein (e.g., the conductive contacts 122, 124, 144, and/or 146) may include bond pads, solder bumps, conductive posts, or any other suitable conductive contact, for example. In some embodiments, some or all of the DTD interconnects 130 and/or the DTS interconnects 140 in a microelectronic assembly 100 may be solder interconnects that include a solder with a higher melting point than a solder included in some or all of the STPS interconnects 150. For example, when the DTD interconnects 130 and the DTS interconnects 140 in a microelectronic assembly 100 are formed before the STPS interconnects 150 are formed, solder-based DTD interconnects 130 and DTS interconnects 140 may use a higher-temperature solder (e.g., with a melting point above 200 degrees Celsius), while the STPS interconnects 150 may use a lower-temperature solder (e.g., with a melting point below 200 degrees Celsius). In some embodiments, a higher-temperature solder may include tin; tin and gold; or tin, silver, and copper (e.g., 96.5% tin, 3% silver, and 0.5% copper). In some embodiments, a lower-temperature solder may include tin and bismuth (e.g., eutectic tin bismuth) or tin, silver, and bismuth. In some embodiments, a lower-temperature solder may include indium, indium and tin, or gallium.

In the microelectronic assemblies 100 disclosed herein, some or all of the DTS interconnects 140 and the STPS interconnects 150 may have a larger pitch than some or all of the DTD interconnects 130. DTD interconnects 130 may have a smaller pitch than STPS interconnects 150 due to the greater similarity of materials in the different dies 114 on either side of a set of DTD interconnects 130 than between the substrate 107 and the top level dies 114-2, 114-3 on either side of a set of DTS interconnects 140, and between the substrate 107 and the package substrate 102 on either side of a set of STPS interconnects 150. In particular, the differences in the material composition of a substrate 107 and a die 114 or a package substrate 102 may result in differential expansion and contraction due to heat generated during operation (as well as the heat applied during various manufacturing operations). To mitigate damage caused by this differential expansion and contraction (e.g., cracking, solder bridging, etc.), the DTS interconnects 140 and the STPS interconnects 150 may be formed larger and farther apart than DTD interconnects 130, which may experience less thermal stress due to the greater material similarity of the pair of dies 114 on either side of the DTD interconnects. In some embodiments, the DTS interconnects 140 disclosed herein may have a pitch between 25 microns and 250 microns. In some embodiments, the STPS interconnects 150 disclosed herein may have a pitch between 55 microns and 1000 microns, while the DTD interconnects 130 disclosed herein may have a pitch between 25 microns and 100 microns.

The microelectronic assembly 100 of FIG. 1 may also include a circuit board (not shown). The package substrate 102 may be coupled to the circuit board by second-level interconnects at the bottom surface of the package substrate 102. The second-level interconnects may be any suitable second-level interconnects, including solder balls for a ball grid array arrangement, pins in a pin grid array arrangement or lands in a land grid array arrangement. The circuit board may be a motherboard, for example, and may have other components attached to it. The circuit board may include conductive pathways and other conductive contacts for routing power, ground, and signals through the circuit board, as known in the art. In some embodiments, the second-level interconnects may not couple the package substrate 102 to a circuit board, but may instead couple the package substrate 102 to another IC package, an interposer, or any other suitable component. In some embodiments, the substrate 107 may not be coupled to a package substrate 102, but may instead be coupled to a circuit board, such as a PCB.

Although FIG. 1 depicts a microelectronic assembly 100 having a substrate with a particular number of dies 114 and conductive pathways 108 coupled to other dies 114, this number and arrangement are simply illustrative, and a microelectronic assembly 100 may include any desired number and arrangement of dies 114. Although FIG. 1 shows the die 114-1 as a double-sided die and the dies 114-2, 114-3 as single-sided dies, the dies 114-2, 114-3 may be double-sided dies and the dies 114 may be a single-pitch die or a mixed-pitch die. In some embodiments, additional components may be disposed on the top surface of the dies 114-2 and/or 114-3. In this context, a double-sided die refers to a die that has connections on both surfaces. In some embodiments, a double-sided die may include through TSVs to form connections on both surfaces. The active surface of a double-sided die, which is the surface containing one or more active devices and a majority of interconnects, may face either direction depending on the design and electrical requirements.

Many of the elements of the microelectronic assembly 100 of FIG. 1 are included in other ones of the accompanying drawings; the discussion of these elements is not repeated when discussing these drawings, and any of these elements may take any of the forms disclosed herein. Further, a number of elements are illustrated in FIG. 1 as included in the microelectronic assembly 100, but a number of these elements may not be present in a microelectronic assembly 100. For example, in various embodiments, the core 109, the further layers 111, the underfill material 127, and the package substrate 102 may not be included. In some embodiments, individual ones of the microelectronic assemblies 100 disclosed herein may serve as a system-in-package (SiP) in which multiple dies 114 having different functionality are included. In such embodiments, the microelectronic assembly 100 may be referred to as an SiP.

### Example Process for Forming Assembly with Doped Dielectric Layers and Embedded Bridge Die

Any suitable techniques may be used to manufacture the microelectronic assembly 100 disclosed herein. FIG. 2 illustrates one example process 200 that may be used to manufacture the microelectronic assembly 100. FIGS. 3A-3M are side, cross-sectional views of various stages in the example process 200. Although the operations discussed below with reference to FIGS. 2 and 3 (and others of the accompanying drawings representing manufacturing processes) are illustrated in a particular order, these operations may be performed in any suitable order. Further, additional operations which are not illustrated may also be performed without departing from the scope of the present disclosure. Also, various ones of the operations discussed herein with respect to FIGS. 2 and 3 may be modified in accordance with the present disclosure to fabricate others of microelectronic assembly 100 disclosed herein.

At 205, a doped dielectric material (e.g., a layer of the doped dielectric material 110) is deposited on a substrate, such as one or more base layers of the substrate 107. FIG. 3A illustrates an assembly that includes a first portion of a substrate, e.g., a first portion of the substrate 107. The portion illustrated in FIG. 3A may be referred to as a preliminary substrate. The preliminary substrate includes a carrier 302. The carrier 302 may include any suitable material for providing mechanical stability during manufacturing operations, such as glass, or may include a core (e.g., the core 109) with or without through vias (e.g., the through vias 115 as shown in FIG. 1). In this example, the carrier 302 includes vias formed from a conductive material 306.

The preliminary substrate further includes a dielectric material 304, which may be the dielectric material 112, and patterned conductive material 306. In this example, the dielectric material 304 and conductive material 306 are on a lower side of the carrier 302. In other examples, the dielectric material 304 and/or conductive material 306 may not be on the lower side of the carrier 302. In addition, patterned conductive material 306 is on the upper side of the carrier 302. The patterned conductive material 306 on the upper side of the carrier 302 may correspond to the N-5 metal layer shown in FIG. 1. The assembly of FIG. 3A may be manufactured using conventional package substrate manufacturing techniques.

FIG. 3B illustrates an assembly after the process 205 of depositing a layer 320 of a doped dielectric material 308 over the preliminary substrate. The layer 320 of the doped dielectric material 308 may correspond to the layer 116 in FIG. 1. The doped dielectric material 308 may include any suitable dielectric material with a dopant mixed in. The dielectric material may include a polymer such as a polyimide, or any of the other dielectric materials described above, e.g., any dielectric materials used for build-up films. The dopant is a catalyst for a metal plating process, e.g., for electroless plating of copper or another metal. The dopant may be, for example, palladium in an ionic form. In other examples, the dopant may be or include platinum, gold, silver, copper, or an alloy of palladium, platinum, gold, silver, copper, and/or other materials. The dopant may be activated using laser ablation, where a laser removes the dielectric material and activates the dopant at the surface to form a seed layer for plating the conductive material. This activation step is shown and described further below.

The doped dielectric material 308 may be a build-up film or another laminate. The layer 320 of the doped dielectric material may be deposited using lamination or another suitable method; if lamination is used, multiple layers of the laminate may form the layer 320.

At 210, conductive structures are formed in the doped dielectric material. For example, openings for the conductive structures may be etched using lithographic patterning, and the conductive material 108 may be deposited in the openings. Alternatively, the doped dielectric material may be selectively etched using laser ablation, and the conductive material may be selectively plated in the openings, as described with respect to processes 230-240 and FIGS. 3G-3I.

FIG. 3C illustrates an assembly after the process 210 of forming the conductive structures in the layer 320 of doped dielectric material. The conductive material 306 has been formed (e.g., by plating or deposition) in the via openings through the layer 320. For example, the via 322 is coupled to a conductive structure 323 that extends through the carrier 302. In addition, traces are formed along the upper surface of the layer 320. This layer corresponds to the layer N-4 in FIG. 1. For example, the conductive contact 324 is formed over the via 322 at or over the top surface of the layer 320. In addition, a plate 326 of the conductive material 306 is arranged along or over a portion of the layer 320. The plate 326 may extend both in the x-direction (e.g., across the layer 320 in the orientation shown) and in the y-direction (e.g., into and/or out of the page). Thus, the plate 326 may be a substantially rectangular or square plane when viewed from the top. The plate 326 may have a surface area in the x-y plane that is at least as large as a surface area of the embedded bridge die.

At 215, metal layers in standard (e.g., undoped) dielectric are formed over the substrate. For example, one or more layers of a dielectric material 112 may be formed over the layer 116, and conductive material 108 may be formed within portions of the dielectric material 112, using standard substrate manufacturing techniques.

FIG. 3D illustrates a layer 330 over the layer 320, where the layer 330 includes the dielectric material 304 and conductive structures (e.g., vias and traces) formed within the dielectric material 304. The layer 330 may correspond to the layer 117 of FIG. 1. Referring to the layers illustrated in FIG. 1, the layers N-3 and N-2 are formed in FIG. 3D. In this example, no conductive vias or traces are formed in the region over the plate 326. In other examples, dummy conductive material may be formed in this region and removed later in the process. A top surface of the layer 330 may be planarized using chemical-mechanical polishing (CMP) or any other suitable process.

At 220, another layer of doped dielectric material is deposited. For example, one or more layers of a laminate that includes a dielectric with the dopant (e.g., ionic palladium) mixed in may be layered over the substrate. The same deposition process (e.g., lamination) and material (e.g., polymer and dopant mixture) as the process 205 may be used at process 220. FIG. 3E illustrates a layer 332 of the doped dielectric material 308 over the layer 330. The layer 332 may correspond to the layer 118 in FIG. 1. In some embodiments, an additional layer of undoped dielectric material (e.g., another layer of the dielectric material 304) is layered over the doped dielectric material 308. The top undoped dielectric layer may help ensure that selective metallization only occurs at intended locations (e.g., via and trace openings formed by laser ablation, as described below) rather than across the top of layer 332.

At 225, a cavity is etched in the doped dielectric material, the standard dielectric material below the etched doped dielectric material, and the plate below the etched dielectric materials. In the example of FIG. 3, the cavity is etched in at least a portion of the region of the substrate formed over the plate 326. The cavity may be formed using any suitable techniques, such as laser patterning techniques or lithography. The cavity etch may be performed using multiple etching processes, e.g., a first process to remove the dielectric materials 304 and 308, and a second process to remove the plate 326. The plate of conductive material may act as an etch stop during the first etching process, e.g., to protect the doped dielectric layer below the plate. A second etching process may selectively remove the exposed plate while preserving the doped dielectric layer below the plate. As a result of the cavity etching process, a portion of the layer of the doped dielectric material 308 below the cavity is exposed.

FIG. 3F illustrates an assembly after forming a cavity 340 through the layers 332 and 330. In this example, the cavity 340 extends through the plate 326 to expose a portion of the doped dielectric material 308 in the layer 320. As viewed in the cross-section, two regions 342a and 342b of the plate 326 formed from the conductive material 306 remain in the substrate. As noted above, the plate 326 is substantially a rectangular or square plane that also extends in the y-direction in the coordinate system shown. In a top-down view, after the cavity 340 is etched, an outer ring of the plate 326 (e.g., a rectangular or square ring, with a rectangular or square opening near the center) may remain in the substrate. As described above, the plate 326 served as an etch stop during etching of the layers 330 and 332, to protect the layer 320 during the dielectric etching process.

In this example, the walls 344a and 344b of the cavity 340 are sloped as a result of the etching process. The edges of the conductive regions 342a and 342b are also sloped, so that they extend at a diagonal rather than vertically. The conductive regions 342a and 342b may not be conductively coupled to any other conductive structures.

At 230, vias are patterned in the doped dielectric material. Vias openings are patterned at the current uppermost portion of the substrate as well as within the cavity. The vias may be patterned using a laser ablation process, which removes dielectric in the doped dielectric material while leaving the dopant in the via openings, so that the dopant can be used as a seed material for a plating process. In some embodiments, an excimer laser (also referred to as an exciplex laser) is used. The laser process may enable precise placement of the via openings both alongside the cavity (e.g., in layer 332) and in the cavity (e.g., in the exposed portion of the layer 320). A desmear process may be performed to remove any loose residue from the laser ablation.

FIG. 3G illustrates an assembly after forming via openings in the doped dielectric material. In this example, some via openings (e.g., the via opening 344) are patterned in the layer 332, and some via openings (e.g., the via opening 346) are patterned in the layer 320 (below the cavity). A layer of the dopant 310 (e.g., palladium) is formed along the walls of the via openings.

At 235, traces are patterned in the doped dielectric material. A similar process to 230 is performed, but the patterned trace openings are generally shallower than the via openings and have larger surface areas. At least some of the trace openings may be patterned around the tops of the previously patterned via openings.

FIG. 3H illustrates an assembly after forming openings for traces in the doped dielectric material. In this example, some trace openings (e.g., the trace opening 348, formed around the via opening 344) are patterned in the layer 332, and some trace openings (e.g., trace opening 350, formed around the via opening 346) are patterned in the layer 320 (at the base of the cavity 340). As with the via openings, a layer of the dopant 310 (e.g., palladium) is formed along the walls of the trace openings.

At 240, conductive material is plated in the patterned regions. For example, copper or another metal may be grown using an electroless deposition process or an electroplating process. The conductive material is deposited or plated over the dopant, which acts as a seed material for the plating process. The seed layer is a suitable material for growing regions of another material, e.g., copper or another conductive material. In general, a seed layer is a thin initial coating of a material (e.g., a metal) that acts as a nucleation site for a subsequent growth process. In this example, the laser ablation process on the doped dielectric layer provides the seed layer. If the seed layer is a different material from the grown conductive material (e.g., a palladium seed for copper growth), the seed material may remain at the base of the grown conductive regions, e.g., as a liner material.

FIG. 3I illustrates an assembly after the process 240 of forming the conductive material in the patterned via openings and trace openings. The conductive material 306 has been formed (e.g., by electroless plating) in the via openings, including the openings 344, 346, 348, and 350, forming vias and traces, e.g., traces 352 and 354. While not specifically illustrated, a layer of the dopant (e.g., a layer of palladium 310) may remain in the vias and traces, and may be observable as a liner material lining the vias and traces, e.g., in the same position as the palladium 310 in FIG. 3H. The process 240 results in simultaneous plating of conductive vias and traces in the layer 332 (in a region around the cavity 340) and the layer 320 (in a region under the cavity).

In FIG. 3I, the conductive material 306 formed in the openings 344, 346, 348, and 350 have substantially flat upper surfaces extending along the upper surface of the layers 320 and 332. For example, the upper surfaces of the traces 352 and 354 are substantially flat and in-plane with the upper surface of the layers 320 and 332, respectively. In some cases, as a result of the deposition process, the upper surfaces of the conductive traces may not be flat, but instead extend above the upper surface of the layers 320 and/or 332. While the upper surface of the layer 332 can be planarized, resulting in the traces in this layer (e.g., trace 354) being made substantially flat and in-plane with the upper surface of the layer 332, within the cavity, the traces (e.g., the trace 352) may not be planarized. An example of this is illustrated in FIG. 4A.

Furthermore, in some embodiments, the process 235 for forming the trace openings is omitted, and traces are not formed. Instead, the upper surfaces of the vias are used as contacts for subsequent layers. An example of this is shown in FIG. 4B.

At 245, a bridge die is bonded to the substrate in the cavity. A lower face of the bridge die may be bonded to the upper face of the cavity, including the traces formed in the layer 320. For example, interconnects formed using solder bonds may be used to bond the bridge die to the substrate. The solder interconnects may have a finer pitch than the STPS interconnects 150 shown in FIG. 1, and may have a pitch similar to the DTD interconnects 130. The solder interconnects may be similar to the DTD interconnects 130 described above. More generally, the interconnects between the bridge die and the substrate in the cavity may include any of the conductive contacts disclosed herein, and may include bond pads, solder bumps, conductive posts, or any other suitable conductive contacts, for example. An underfill material, e.g., the underfill material 127 described above, may be provided between the interconnects.

FIG. 3J illustrates an assembly after the process 245 of bonding the bridge die to the substrate. A bridge die 360, which may be the bridge die 114-1 of FIG. 1, is positioned in the cavity 340. The bridge die 360 includes conductive contacts at its top and bottom faces, and conductive pathways formed therein (e.g., vias between the conductive contacts). The conductive contacts (e.g., the conductive contacts 122) at the lower face of the bridge die 360 are bonded to the traces formed in the doped dielectric material 308 along the upper face of the layer 320 by solder bonds 312. An underfill material 314 fills the area between the solder bonds 312, below the bridge die 360 and above the layer 320. A portion 362 of the cavity 340 remains between the edges of the bridge die 360 and the dielectric material 304, surrounding the bridge die 360; this portion 362 of the cavity may be filled in with additional dielectric (e.g., at process 250).

At 250, conductive structures are formed over the bridge die. For example, additional dielectric material 304 is deposited around and over the bridge die 360, and additional conductive structures are formed over the bridge die 360. FIG. 3K illustrates an assembly after the process 250 of forming conductive structures over the bridge die 360. These additional conductive structures are coupled to the upper contacts in the bridge die, e.g., the conductive contacts 124 of FIG. 1. The conductive structures are in the same layer 332 as the second layer of doped dielectric material.

At 255, additional metal layers are formed over the substrate. For example, the layer 119 of FIG. 1 may be deposited over the substrate. In other embodiments, more additional metal layers may be formed. In other embodiments, no additional metal layers are formed.

FIG. 3L illustrates an assembly after the process 255 of forming an additional metal layer over the substrate. FIG. 3L includes a layer 370, which corresponds to the layer 119 in FIG. 1. In this example, a layer of the dielectric material 304 is deposited, and conductive structures are formed therein. The assembly shown in FIG. 3L may be a substrate to which additional dies (e.g., the dies 114-2 and 114-3) are attached. The substrate includes an embedded bridge die 360, and vias (e.g., via 372) coupled to the embedded bridge die 360 and extending to an upper face of the substrate. The substrate further includes through-substrate vias (e.g., via 374) that extends from a lower face of the substrate to an upper face of the substrate. In this example, the through-substrate vias extend alongside the bridge die 360 and are not in physical or electrical contact with the bridge die 360.

At 260, dies are bonded to the upper face of the substrate and coupled to the bridge die (e.g., by vias formed over the bridge die) and through-substrate vias. For example, additional dies, such as the dies 114-2 and 114-3 described with respect to FIG. 1, are coupled to the substrate, e.g., using direct bonding or a solder bonding process described with respect to FIG. 1.

FIG. 3M illustrates an assembly after the process 260 of attaching dies to the substrate. In this example, two dies 380 and 382 are attached to the substrate. The dies 380 and 382 are electrically coupled to the bridge die 360, as described with respect to FIG. 1. For example, the via 372 couples the die 382 to the bridge die 360. The dies 380 and 382 may also be electrically coupled to through-substrate vias, e.g., the die 382 is coupled to the through-substrate via 374. The dies 380 and 382 may be coupled to the substrate via solder bonds 312 that are surrounded by an underfill material 314, as shown in FIG. 1 and described above.

### Alternate Conductive Structures in Doped Dielectric Layers

FIG. 4A and 4B illustrate alternate configurations of conductive structures in doped dielectric layers, in accordance with various embodiments. As noted above, in some cases, the deposition process 240 results in conductive structures in the doped dielectric layers that do not have flat upper surfaces, but instead have surfaces that extend above the upper surface of the layers 320 and/or 332. FIG. 4A illustrates an example assembly after processing step 345 (bonding the bridge die in the cavity) in which the upper surfaces of the conductive structures in the layer 320 are not flat and have not been planarized. For example, the contact 410 has a rounded top that extends above the upper surface of the doped dielectric in the layer 320. By contrast, the upper plane of the assembly has been planarized, so that traces along the upper surface, such as trace 412, are flat and along the plane of the doped dielectric in the layer 332. In the illustration of FIG. 4A, the bridge die 360 has been bonded in the cavity, over the contacts including contact 410. It should be understood that the remainder of the processing steps 250-260 can be performed, resulting in an assembly similar to that shown in FIG. 1, but with rounded contacts at the base of the cavity. In some embodiments, the contacts in the upper doped dielectric layer (e.g., the trace 412) may not be planarized and have a similar shape to the contact 410.

FIG. 4B illustrates another alternate assembly in which the process 235 of forming the trace openings is omitted, and traces are not formed. Instead, the upper surfaces of vias formed in the doped dielectric layers are used as contacts for subsequent layers. The vias may have rounded surfaces, similar to the contact 410 of FIG. 4A. For example, the via 420 at the base of the cavity has a rounded upper surface. In this example, the via 422 in the upper dielectric layer has a flat surface, which may result from planarizing the upper surface of the assembly shown in FIG. 4B. In alternate configurations, the via 422 and other vias along the top of the assembly in FIG. 4B are not planarized, and instead have upper surfaces with the rounded shape of the via 420. The bridge die 360 may be bonded over the rounded vias in the cavity (e.g., the via 420) in a similar manner as described in step 245 and illustrated in FIGS. 3J and 4A, and the further processing steps 250-260 may be performed.

### Example Devices

The microelectronic assemblies 100 disclosed herein may be included in any suitable electronic component. FIGS. 5-8 illustrate various examples of apparatuses that may include, or be included in, any of the microelectronic assemblies 100 disclosed herein.

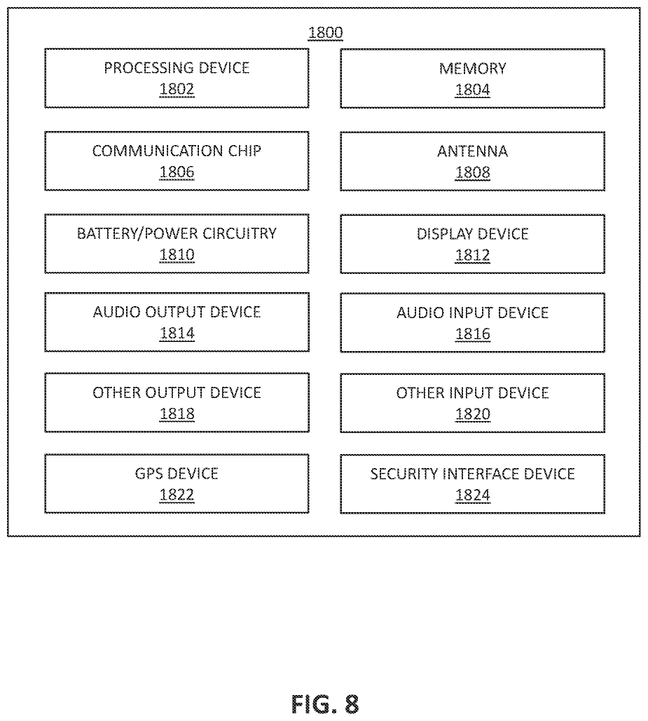

FIG. 5 is a top view of a wafer 1500 and dies 1502 that may be included in any of the microelectronic assemblies 100 disclosed herein (e.g., as any suitable ones of the dies 114). The wafer 1500 may be composed of semiconductor material and may include one or more dies 1502 having IC structures formed on a surface of the wafer 1500. Each of the dies 1502 may be a repeating unit of a semiconductor product that includes any suitable IC. After the fabrication of the semiconductor product is complete, the wafer 1500 may undergo a singulation process in which the dies 1502 are separated from one another to provide discrete “chips” of the semiconductor product. The die 1502 may be any of the dies 114 disclosed herein. The die 1502 may include one or more transistors (e.g., some of the transistors 1640 of FIG. 6, discussed below), supporting circuitry to route electrical signals to the transistors, passive components (e.g., signal traces, resistors, capacitors, or inductors), and/or any other IC components. In some embodiments, the wafer 1500 or the die 1502 may include a memory device (e.g., a random access memory (RAM) device, such as a static RAM (SRAM) device, a magnetic RAM (MRAM) device, a resistive RAM (RRAM) device, a conductive-bridging RAM (CBRAM) device, etc.), a logic device (e.g., an AND, OR, NAND, or NOR gate), or any other suitable circuit element. Multiple ones of these devices may be combined on a single die 1502. For example, a memory array formed by multiple memory devices may be formed on a same die 1502 as a processing device (e.g., the processing device 1802 of FIG. 8) or other logic that is configured to store information in the memory devices or execute instructions stored in the memory array. In some embodiments, a die 1502 (e.g., a die 114) may be a central processing unit, a radio frequency chip, a power converter, or a network processor. Various ones of the microelectronic assemblies 100 disclosed herein may be manufactured using a die-to-wafer assembly technique in which some dies 114 are attached to a wafer 1500 that include others of the dies 114, and the wafer 1500 is subsequently singulated.

FIG. 6 is a cross-sectional side view of an IC device 1600 that may be included in any of the microelectronic assemblies 100 disclosed herein (e.g., in any of the dies 114). One or more of the IC devices 1600 may be included in one or more dies 1502 (FIG. 5). The IC device 1600 may be formed on a die substrate 1602 (e.g., the wafer 1500 of FIG. 5) and may be included in a die (e.g., the die 1502 of FIG. 5). The die substrate 1602 may be a semiconductor substrate composed of semiconductor material systems including, for example, n-type or p-type materials systems (or a combination of both). The die substrate 1602 may include, for example, a crystalline substrate formed using a bulk silicon or a silicon-on-insulator (SOI) substructure. In some embodiments, the die substrate 1602 may be formed using alternative materials, which may or may not be combined with silicon, that include, but are not limited to, germanium, indium antimonide, lead telluride, indium arsenide, indium phosphide, gallium arsenide, or gallium antimonide. Further materials classified as group II-VI, III-V, or IV may also be used to form the die substrate 1602. Although a few examples of materials from which the die substrate 1602 may be formed are described here, any material that may serve as a foundation for an IC device 1600 may be used. The die substrate 1602 may be part of a singulated die (e.g., the dies 1502 of FIG. 5) or a wafer (e.g., the wafer 1500 of FIG. 5).

The IC device 1600 may include one or more device layers 1604 disposed on the die substrate 1602. The device layer 1604 may include features of one or more transistors 1640 (e.g., metal oxide semiconductor field-effect transistors (MOSFETs)) formed on the die substrate 1602. The device layer 1604 may include, for example, one or more source and/or drain (S/D) regions 1620, a gate 1622 to control current flow in the transistors 1640 between the S/D regions 1620, and one or more S/D contacts 1624 to route electrical signals to/from the S/D regions 1620. The transistors 1640 may include additional features not depicted for the sake of clarity, such as device isolation regions, gate contacts, and the like. The transistors 1640 are not limited to the type and configuration depicted in FIG. 6 and may include a wide variety of other types and configurations such as, for example, planar transistors, non-planar transistors, or a combination of both. Non-planar transistors may include FinFET transistors, such as double-gate transistors or tri-gate transistors, and wrap-around or all-around gate transistors, such as nanoribbon and nanowire transistors.

Each transistor 1640 may include a gate 1622 formed of at least two layers, a gate dielectric and a gate electrode. The gate dielectric may include one layer or a stack of layers. The one or more layers may include silicon oxide, silicon dioxide, silicon carbide, and/or a high-k dielectric material. The high-k dielectric material may include elements such as hafnium, silicon, oxygen, titanium, tantalum, lanthanum, aluminum, zirconium, barium, strontium, yttrium, lead, scandium, niobium, and zinc. Examples of high-k materials that may be used in the gate dielectric include, but are not limited to, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate. In some embodiments, an annealing process may be carried out on the gate dielectric to improve its quality when a high-k material is used.

The gate electrode may be formed on the gate dielectric and may include at least one p-type work function metal or n-type work function metal, depending on whether the transistor 1640 is to be a PMOS or a NMOS transistor. In some implementations, the gate electrode may consist of a stack of two or more metal layers, where one or more metal layers are work function metal layers and at least one metal layer is a fill metal layer. Further metal layers may be included for other purposes, such as a barrier layer. For a PMOS transistor, metals that may be used for the gate electrode include, but are not limited to, ruthenium, palladium, platinum, cobalt, nickel, conductive metal oxides (e.g., ruthenium oxide), and any of the metals discussed below with reference to an NMOS transistor (e.g., for work function tuning). For an NMOS transistor, metals that may be used for the gate electrode include, but are not limited to, hafnium, zirconium, titanium, tantalum, aluminum, alloys of these metals, carbides of these metals (e.g., hafnium carbide, zirconium carbide, titanium carbide, tantalum carbide, and aluminum carbide), and any of the metals discussed above with reference to a PMOS transistor (e.g., for work function tuning).

In some embodiments, when viewed as a cross-section of the transistor 1640 along the source-channel-drain direction, the gate electrode may consist of a U-shaped structure that includes a bottom portion substantially parallel to the surface of the die substrate 1602 and two sidewall portions that are substantially perpendicular to the top surface of the die substrate 1602. In other embodiments, at least one of the metal layers that form the gate electrode may simply be a planar layer that is substantially parallel to the top surface of the die substrate 1602 and does not include sidewall portions substantially perpendicular to the top surface of the die substrate 1602. In other embodiments, the gate electrode may consist of a combination of U-shaped structures and planar, non-U-shaped structures. For example, the gate electrode may consist of one or more U-shaped metal layers formed atop one or more planar, non-U-shaped layers.

In some embodiments, a pair of sidewall spacers may be formed on opposing sides of the gate stack to bracket the gate stack. The sidewall spacers may be formed from materials such as silicon nitride, silicon oxide, silicon carbide, silicon nitride doped with carbon, and silicon oxynitride. Processes for forming sidewall spacers are well known in the art and generally include deposition and etching process steps. In some embodiments, a plurality of spacer pairs may be used; for instance, two pairs, three pairs, or four pairs of sidewall spacers may be formed on opposing sides of the gate stack.

The S/D regions 1620 may be formed within the die substrate 1602 adjacent to the gate 1622 of each transistor 1640. The S/D regions 1620 may be formed using an implantation/diffusion process or an etching/deposition process, for example. In the former process, dopants such as boron, aluminum, antimony, phosphorous, or arsenic may be ion-implanted into the die substrate 1602 to form the S/D regions 1620. An annealing process that activates the dopants and causes them to diffuse farther into the die substrate 1602 may follow the ion-implantation process. In the latter process, the die substrate 1602 may first be etched to form recesses at the locations of the S/D regions 1620. An epitaxial deposition process may then be carried out to fill the recesses with material that is used to fabricate the S/D regions 1620. In some implementations, the S/D regions 1620 may be fabricated using a silicon alloy such as silicon germanium or silicon carbide. In some embodiments, the epitaxially deposited silicon alloy may be doped in situ with dopants such as boron, arsenic, or phosphorous. In some embodiments, the S/D regions 1620 may be formed using one or more alternate semiconductor materials such as germanium or a group III-V material or alloy. In further embodiments, one or more layers of metal and/or metal alloys may be used to form the S/D regions 1620.

Electrical signals, such as power and/or input/output (I/O) signals, may be routed to and/or from the devices (e.g., transistors 1640) of the device layer 1604 through one or more interconnect layers disposed on the device layer 1604 (illustrated in FIG. 6 as interconnect layers 1606-1610). For example, electrically conductive features of the device layer 1604 (e.g., the gate 1622 and the S/D contacts 1624) may be electrically coupled with the interconnect structures 1628 of the interconnect layers 1606-1610. The one or more interconnect layers 1606-1610 may form a metallization stack (also referred to as an “ILD stack”) 1619 of the IC device 1600.

The interconnect structures 1628 may be arranged within the interconnect layers 1606-1610 to route electrical signals according to a wide variety of designs; in particular, the arrangement is not limited to the particular configuration of interconnect structures 1628 depicted in FIG. 6. Although a particular number of interconnect layers 1606-1610 is depicted in FIG. 6, embodiments of the present disclosure include IC devices having more or fewer interconnect layers than depicted.

In some embodiments, the interconnect structures 1628 may include lines 1628a and/or vias 1628b filled with an electrically conductive material such as a metal. The lines 1628a may be arranged to route electrical signals in a direction of a plane that is substantially parallel with a surface of the die substrate 1602 upon which the device layer 1604 is formed. For example, the lines 1628a may route electrical signals in a direction in and out of the page from the perspective of FIG. 6. The vias 1628b may be arranged to route electrical signals in a direction of a plane that is substantially perpendicular to the surface of the die substrate 1602 upon which the device layer 1604 is formed. In some embodiments, the vias 1628b may electrically couple lines 1628a of different interconnect layers 1606-1610 together.

The interconnect layers 1606-1610 may include a dielectric material 1626 disposed between the interconnect structures 1628, as shown in FIG. 6. In some embodiments, the dielectric material 1626 disposed between the interconnect structures 1628 in different ones of the interconnect layers 1606-1610 may have different compositions; in other embodiments, the composition of the dielectric material 1626 between different interconnect layers 1606-1610 may be the same.

A first interconnect layer 1606 (referred to as Metal 1 or “M1”) may be formed directly on the device layer 1604. In some embodiments, the first interconnect layer 1606 may include lines 1628a and/or vias 1628b, as shown. The lines 1628a of the first interconnect layer 1606 may be coupled with contacts (e.g., the S/D contacts 1624) of the device layer 1604.

A second interconnect layer 1608 (referred to as Metal 2 or “M2”) may be formed directly on the first interconnect layer 1606. In some embodiments, the second interconnect layer 1608 may include vias 1628b to couple the lines 1628a of the second interconnect layer 1608 with the lines 1628a of the first interconnect layer 1606. Although the lines 1628a and the vias 1628b are structurally delineated with a line within each interconnect layer (e.g., within the second interconnect layer 1608) for the sake of clarity, the lines 1628a and the vias 1628b may be structurally and/or materially contiguous (e.g., simultaneously filled during a dual damascene process) in some embodiments.

A third interconnect layer 1610 (referred to as Metal 3 or “M3”) (and additional interconnect layers, as desired) may be formed in succession on the second interconnect layer 1608 according to similar techniques and configurations described in connection with the second interconnect layer 1608 or the first interconnect layer 1606. In some embodiments, the interconnect layers that are “higher up” in the metallization stack 1619 in the IC device 1600 (i.e., farther away from the device layer 1604) may be thicker.

The IC device 1600 may include a solder resist material 1634 (e.g., polyimide or similar material) and one or more conductive contacts 1636 formed on the interconnect layers 1606-1610. In FIG. 6, the conductive contacts 1636 are illustrated as taking the form of bond pads. The conductive contacts 1636 may be electrically coupled with the interconnect structures 1628 and configured to route the electrical signals of the transistor(s) 1640 to other external devices. For example, solder bonds may be formed on the one or more conductive contacts 1636 to mechanically and/or electrically couple a chip including the IC device 1600 with another component (e.g., a circuit board). The IC device 1600 may include additional or alternate structures to route the electrical signals from the interconnect layers 1606-1610; for example, the conductive contacts 1636 may include other analogous features (e.g., posts) that route the electrical signals to external components.

In some embodiments in which the IC device 1600 is a double-sided die (e.g., like the die 114-1), the IC device 1600 may include another metallization stack (not shown) on the opposite side of the device layer(s) 1604. This metallization stack may include multiple interconnect layers as discussed above with reference to the interconnect layers 1606-1610, to provide conductive pathways (e.g., including conductive lines and vias) between the device layer(s) 1604 and additional conductive contacts (not shown) on the opposite side of the IC device 1600 from the conductive contacts 1636.

In other embodiments in which the IC device 1600 is a double-sided die (e.g., like the die 114-1), the IC device 1600 may include one or more TSVs through the die substrate 1602; these TSVs may make contact with the device layer(s) 1604, and may provide conductive pathways between the device layer(s) 1604 and additional conductive contacts (not shown) on the opposite side of the IC device 1600 from the conductive contacts 1636.

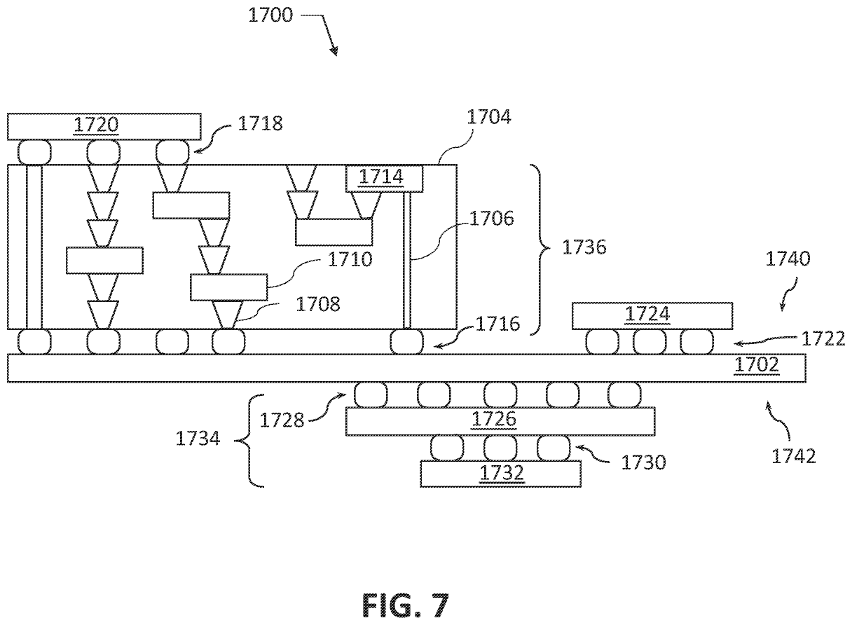

FIG. 7 is a cross-sectional side view of an IC device assembly 1700 that may include any of the microelectronic assemblies 100 disclosed herein. In some embodiments, the IC device assembly 1700 may be a microelectronic assembly 100. The IC device assembly 1700 includes a number of components disposed on a circuit board 1702 (which may be, e.g., a motherboard). The IC device assembly 1700 includes components disposed on a first face 1740 of the circuit board 1702 and an opposing second face 1742 of the circuit board 1702; generally, components may be disposed on one or both faces 1740 and 1742. Any of the IC packages discussed below with reference to the IC device assembly 1700 may take the form of any suitable ones of the embodiments of the microelectronic assemblies 100 disclosed herein.

In some embodiments, the circuit board 1702 may be a PCB including multiple metal layers separated from one another by layers of dielectric material and interconnected by electrically conductive vias. Any one or more of the metal layers may be formed in a desired circuit pattern to route electrical signals (optionally in conjunction with other metal layers) between the components coupled to the circuit board 1702. In other embodiments, the circuit board 1702 may be a non-PCB substrate. In some embodiments the circuit board 1702 may be, for example, a circuit board.

The IC device assembly 1700 illustrated in FIG. 7 includes a package-on-interposer structure 1736 coupled to the first face 1740 of the circuit board 1702 by coupling components 1716. The coupling components 1716 may electrically and mechanically couple the package-on-interposer structure 1736 to the circuit board 1702, and may include solder balls (as shown in FIG. 7), male and female portions of a socket, an adhesive, an underfill material, and/or any other suitable electrical and/or mechanical coupling structure.

The package-on-interposer structure 1736 may include an IC package 1720 coupled to an interposer 1704 by coupling components 1718. The coupling components 1718 may take any suitable form for the application, such as the forms discussed above with reference to the coupling components 1716. Although a single IC package 1720 is shown in FIG. 7, multiple IC packages may be coupled to the interposer 1704; indeed, additional interposers may be coupled to the interposer 1704. The interposer 1704 may provide an intervening substrate used to bridge the circuit board 1702 and the IC package 1720. The IC package 1720 may be or include, for example, a die (the die 1502 of FIG. 5), an IC device (e.g., the IC device 1600 of FIG. 6), or any other suitable component. Generally, the interposer 1704 may spread a connection to a wider pitch or reroute a connection to a different connection. For example, the interposer 1704 may couple the IC package 1720 (e.g., a die) to a set of ball grid array (BGA) conductive contacts of the coupling components 1716 for coupling to the circuit board 1702. In the embodiment illustrated in FIG. 7, the IC package 1720 and the circuit board 1702 are attached to opposing sides of the interposer 1704; in other embodiments, the IC package 1720 and the circuit board 1702 may be attached to a same side of the interposer 1704. In some embodiments, three or more components may be interconnected by way of the interposer 1704.

In some embodiments, the interposer 1704 may be formed as a PCB, including multiple metal layers separated from one another by layers of dielectric material and interconnected by electrically conductive vias. In some embodiments, the interposer 1704 may be formed of an epoxy resin, a fiberglass-reinforced epoxy resin, an epoxy resin with inorganic fillers, a ceramic material, or a polymer material such as polyimide. In some embodiments, the interposer 1704 may be formed of alternate rigid or flexible materials that may include the same materials described above for use in a semiconductor substrate, such as silicon, germanium, and other group III-V and group IV materials. The interposer 1704 may include metal interconnects 1708 and vias 1710, including but not limited to TSVs 1706. The interposer 1704 may further include embedded devices 1714, including both passive and active devices. Such devices may include, but are not limited to, capacitors, decoupling capacitors, resistors, inductors, fuses, diodes, transformers, sensors, electrostatic discharge (ESD) devices, and memory devices. More complex devices such as radio frequency devices, power amplifiers, power management devices, antennas, arrays, sensors, and microelectromechanical systems (MEMS) devices may also be formed on the interposer 1704. The package-on-interposer structure 1736 may take the form of any of the package-on-interposer structures known in the art.

The IC device assembly 1700 may include an IC package 1724 coupled to the first face 1740 of the circuit board 1702 by coupling components 1722. The coupling components 1722 may take the form of any of the embodiments discussed above with reference to the coupling components 1716, and the IC package 1724 may take the form of any of the embodiments discussed above with reference to the IC package 1720.

The IC device assembly 1700 illustrated in FIG. 7 includes a package-on-package structure 1734 coupled to the second face 1742 of the circuit board 1702 by coupling components 1728. The package-on-package structure 1734 may include an IC package 1726 and an IC package 1732 coupled together by coupling components 1730 such that the IC package 1726 is disposed between the circuit board 1702 and the IC package 1732. The coupling components 1728 and 1730 may take the form of any of the embodiments of the coupling components 1716 discussed above, and the IC packages 1726 and 1732 may take the form of any of the embodiments of the IC package 1720 discussed above. The package-on-package structure 1734 may be configured in accordance with any of the package-on-package structures known in the art.

FIG. 8 is a block diagram of an example electrical device 1800 that may include one or more of the microelectronic assemblies 100 disclosed herein. For example, any suitable ones of the components of the electrical device 1800 may include one or more of the IC device assemblies 1700, IC devices 1600, or dies 1502 disclosed herein, and may be arranged in any of the microelectronic assemblies 100 disclosed herein. A number of components are illustrated in FIG. 8 as included in the electrical device 1800, but any one or more of these components may be omitted or duplicated, as suitable for the application. In some embodiments, some or all of the components included in the electrical device 1800 may be attached to one or more motherboards. In some embodiments, some or all of these components are fabricated onto a single system-on-a-chip (SoC) die.

Additionally, in various embodiments, the electrical device 1800 may not include one or more of the components illustrated in FIG. 8, but the electrical device 1800 may include interface circuitry for coupling to the one or more components. For example, the electrical device 1800 may not include a display device 1806, but may include display device interface circuitry (e.g., a connector and driver circuitry) to which a display device 1806 may be coupled. In another set of examples, the electrical device 1800 may not include an audio input device 1824 or an audio output device 1808, but may include audio input or output device interface circuitry (e.g., connectors and supporting circuitry) to which an audio input device 1824 or audio output device 1808 may be coupled.

The electrical device 1800 may include a processing device 1802 (e.g., one or more processing devices). As used herein, the term “processing device” or “processor” may refer to any device or portion of a device that processes electronic data from registers and/or memory to transform that electronic data into other electronic data that may be stored in registers and/or memory. The processing device 1802 may include one or more digital signal processors (DSPs), application-specific ICs (ASICs), central processing units (CPUs), graphics processing units (GPUs), cryptoprocessors (specialized processors that execute cryptographic algorithms within hardware), server processors, or any other suitable processing devices. The electrical device 1800 may include a memory 1804, which may itself include one or more memory devices such as volatile memory (e.g., dynamic random access memory (DRAM)), nonvolatile memory (e.g., read-only memory (ROM)), flash memory, solid state memory, and/or a hard drive. In some embodiments, the memory 1804 may include memory that shares a die with the processing device 1802. This memory may be used as cache memory and may include embedded dynamic random access memory (eDRAM) or spin transfer torque magnetic random access memory (STT-MRAM).

In some embodiments, the electrical device 1800 may include a communication chip 1812 (e.g., one or more communication chips). For example, the communication chip 1812 may be configured for managing wireless communications for the transfer of data to and from the electrical device 1800. The term “wireless” and its derivatives may be used to describe circuits, devices, systems, methods, techniques, communications channels, etc., that may communicate data through the use of modulated electromagnetic radiation through a nonsolid medium. The term does not imply that the associated devices do not contain any wires, although in some embodiments they might not.

The communication chip 1812 may implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16-2005 Amendment), Long-Term Evolution (LTE) project along with any amendments, updates, and/or revisions (e.g., advanced LTE project, ultra mobile broadband (UMB) project (also referred to as “3GPP2”), etc.). IEEE 802.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 802.16 standards. The communication chip 1812 may operate in accordance with a Global System for Mobile Communication (GSM), General Packet Radio Service (GPRS), Universal Mobile Telecommunications System (UMLS), High Speed Packet Access (HSPA), Evolved HSPA (E-HSPA), or LTE network. The communication chip 1812 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). The communication chip 1812 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. The communication chip 1812 may operate in accordance with other wireless protocols in other embodiments. The electrical device 1800 may include an antenna 1822 to facilitate wireless communications and/or to receive other wireless communications (such as AM or FM radio transmissions).

In some embodiments, the communication chip 1812 may manage wired communications, such as electrical, optical, or any other suitable communication protocols (e.g., the Ethernet). As noted above, the communication chip 1812 may include multiple communication chips. For instance, a first communication chip 1812 may be dedicated to shorter-range wireless communications such as Wi-Fi or Bluetooth, and a second communication chip 1812 may be dedicated to longer-range wireless communications such as global positioning system (GPS), EDGE, GPRS, CDMA, WiMAX, LTE, EV-DO, or others. In some embodiments, a first communication chip 1812 may be dedicated to wireless communications, and a second communication chip 1812 may be dedicated to wired communications.

The electrical device 1800 may include battery/power circuitry 1814. The battery/power circuitry 1814 may include one or more energy storage devices (e.g., batteries or capacitors) and/or circuitry for coupling components of the electrical device 1800 to an energy source separate from the electrical device 1800 (e.g., AC line power).

The electrical device 1800 may include a display device 1806 (or corresponding interface circuitry, as discussed above). The display device 1806 may include any visual indicators, such as a heads-up display, a computer monitor, a projector, a touchscreen display, a liquid crystal display (LCD), a light-emitting diode display, or a flat panel display.

The electrical device 1800 may include an audio output device 1808 (or corresponding interface circuitry, as discussed above). The audio output device 1808 may include any device that generates an audible indicator, such as speakers, headsets, or earbuds.

The electrical device 1800 may include an audio input device 1824 (or corresponding interface circuitry, as discussed above). The audio input device 1824 may include any device that generates a signal representative of a sound, such as microphones, microphone arrays, or digital instruments (e.g., instruments having a musical instrument digital interface (MIDI) output).

The electrical device 1800 may include a GPS device 1818 (or corresponding interface circuitry, as discussed above). The GPS device 1818 may be in communication with a satellite-based system and may receive a location of the electrical device 1800, as known in the art.

The electrical device 1800 may include an other output device 1810 (or corresponding interface circuitry, as discussed above). Examples of the other output device 1810 may include an audio codec, a video codec, a printer, a wired or wireless transmitter for providing information to other devices, or an additional storage device.

The electrical device 1800 may include an other input device 1820 (or corresponding interface circuitry, as discussed above). Examples of the other input device 1820 may include an accelerometer, a gyroscope, a compass, an image capture device, a keyboard, a cursor control device such as a mouse, a stylus, a touchpad, a bar code reader, a Quick Response (QR) code reader, any sensor, or a radio frequency identification (RFID) reader.

The electrical device 1800 may have any desired form factor, such as a computing device or a hand-held, portable or mobile computing device (e.g., a cell phone, a smart phone, a mobile internet device, a music player, a tablet computer, a laptop computer, a netbook computer, an ultrabook computer, a personal digital assistant (PDA), an ultra mobile personal computer, etc.), a desktop electrical device, a server, or other networked computing component, a printer, a scanner, a monitor, a set-top box, an entertainment control unit, a vehicle control unit, a digital camera, a digital video recorder, or a wearable computing device. In some embodiments, the electrical device 1800 may be any other electronic device that processes data.

### Select Examples

The following paragraphs provide various examples of the embodiments disclosed herein.

Example 1 provides an assembly including a first layer including a first dielectric material and a dopant; a second layer over the first layer, the second layer including a second dielectric material and a bridge component, the bridge component including a plurality of conductive contacts at a first face of the bridge component; and a third layer over the second layer, the third layer including a first portion including the first dielectric material and the dopant; and a second portion including a conductive via coupled to one of the plurality of conductive contacts of the bridge component.

Example 2 provides the assembly of example 1, where the second portion of the third layer further includes the second dielectric material, the second portion extending over the bridge component.

Example 3 provides the assembly of example 1 or 2, where the first portion of the third layer does not extend over the bridge component.

Example 4 provides the assembly of any of the preceding examples, where the first dielectric material and the second dielectric material include a same dielectric material.

Example 5 provides the assembly of any of the preceding examples, where the conductive via includes a first conductive material, and the dopant is a catalyst for growth of the first conductive material.

Example 6 provides the assembly of example 5, where the first conductive material is copper.

Example 7 provides the assembly of any of the preceding examples, where the dopant is palladium.

Example 8 provides the assembly of example 7, where the conductive via includes a palladium liner.

Example 9 provides the assembly of any of the preceding examples, where the bridge component is in a cavity extending through the second layer, the second layer further including, at a lower portion of the second layer directly over the first layer, a copper region adjacent to the cavity.

Example 10 provides the assembly of any of the preceding examples, further including a fourth layer over the third layer, the fourth layer including a third dielectric material.

Example 11 provides the assembly of any of the preceding examples, the first layer including a conductive structure having a rounded upper surface.

Example 12 provides the assembly of example 11, where the rounded upper surface of the conductive structure extends above an upper surface of the first dielectric material.

Example 13 provides the assembly of example 11 or 12, the first portion of the third layer including a conductive structure having a substantially flat upper surface.

Example 14 provides a microelectronic assembly, including a substrate; a bridge component in the substrate, the bridge component including a first plurality of conductive contacts at a first face of the bridge component; and a microelectronic component including a second plurality of conductive contacts at a first face of the microelectronic component, where one of the second plurality of conductive contacts of the microelectronic component is conductively coupled to one of the first plurality of conductive contacts of the bridge component; where the substrate includes a first layer including a dopant, the first layer extending under the bridge component; and a second layer including the dopant, the second layer extending under the microelectronic component.

Example 15 provides the microelectronic assembly of example 14, where the second layer of the substrate includes a first portion that includes the dopant and a second portion that does not include the dopant, where the first portion is under a first region of the microelectronic component, and the second portion is over the bridge component and under a second region of the microelectronic component.

Example 16 provides the microelectronic assembly of example 15, where a through-substrate via extends through the first portion of the second layer, the through-substrate via coupled to a second one of the second plurality of conductive contacts of the microelectronic component.

Example 17 provides the microelectronic assembly of any of examples 14 through 16, the substrate further including a third layer between the first layer and the second layer, the third layer not including the dopant.

Example 18 provides the microelectronic assembly of any of examples 14 through 17, further including a second microelectronic component including a third plurality of conductive contacts at a first face of the second microelectronic component, where one of the third plurality of conductive contacts of the second microelectronic component is conductively coupled to a second one of the first plurality of conductive contacts of the bridge component.

Example 19 provides an assembly including a substrate including a first dielectric layer and a second dielectric layer over the first dielectric layer, the first dielectric layer including a dopant, and the first dielectric layer having a plurality of conductive structures formed therein; a first die having a first face and a second face, the first face of the first die having contacts electrically coupled to the plurality of conductive structures in the first dielectric layer; a second die electrically coupled to the first die at the second face of the first die; and a third die electrically coupled to the first die at the second face of the first die.

Example 20 provides the assembly of example 19, where a first portion of the second die is over the first die, and a second portion of the second die is not over the first die.

Example 21 provides the assembly of example 20, the substrate including a third dielectric layer over the second dielectric layer, the third dielectric layer including the dopant in a region of the third dielectric layer that is under the second portion of the second die.

Example 22 provides the assembly of example 21, where the third dielectric layer includes a second region that does not include the dopant, the second region of the third dielectric layer extending over the first die.

Example 23 provides the assembly of any of examples 19-22, further including a through-substrate via coupled to the second die.

1. An assembly comprising:
a first layer comprising a first dielectric material and a dopant;
a second layer over the first layer, the second layer comprising a second dielectric material and a bridge component, the bridge component comprising a plurality of conductive contacts at a first face of the bridge component; and
a third layer over the second layer, the third layer comprising:
a first portion comprising the first dielectric material and the dopant; and
a second portion comprising a conductive via coupled to one of the plurality of conductive contacts of the bridge component.

2. The assembly of claim 1, wherein the second portion of the third layer further comprises the second dielectric material, the second portion extending over the bridge component.

3. The assembly of claim 1, wherein the first portion of the third layer does not extend over the bridge component.

4. The assembly of claim 1, wherein the first dielectric material and the second dielectric material comprise a same dielectric material.

5. The assembly of claim 1, wherein the conductive via comprises a first conductive material, and the dopant is a catalyst for growth of the first conductive material.

6. The assembly of claim 5, wherein the first conductive material is copper.

7. The assembly of claim 1, wherein the dopant is palladium.

8. The assembly of claim 7, wherein the conductive via comprises a palladium liner.

9. The assembly of claim 1, wherein the bridge component is in a cavity extending through the second layer, the second layer further comprising, at a lower portion of the second layer directly over the first layer, a copper region adjacent to the cavity.

10. The assembly of claim 1, further comprising a fourth layer over the third layer, the fourth layer comprising a third dielectric material.

11. The assembly of claim 1, the first layer comprising a conductive structure having a rounded upper surface.

12. The assembly of claim 11, wherein the rounded upper surface of the conductive structure extends above an upper surface of the first dielectric material.

13. The assembly of claim 11, the first portion of the third layer comprising a conductive structure having a substantially flat upper surface.

14. A microelectronic assembly, comprising:
a substrate;
a bridge component in the substrate, the bridge component comprising a first plurality of conductive contacts at a first face of the bridge component; and
a microelectronic component comprising a second plurality of conductive contacts at a first face of the microelectronic component, wherein one of the second plurality of conductive contacts of the microelectronic component is conductively coupled to one of the first plurality of conductive contacts of the bridge component;
wherein the substrate comprises:
a first layer comprising a dopant, the first layer extending under the bridge component; and
a second layer comprising the dopant, the second layer extending under the microelectronic component.

15. The microelectronic assembly of claim 14, wherein the second layer of the substrate comprises a first portion that includes the dopant and a second portion that does not include the dopant, wherein the first portion is under a first region of the microelectronic component, and the second portion is over the bridge component and under a second region of the microelectronic component.

16. The microelectronic assembly of claim 15, wherein a through-substrate via extends through the first portion of the second layer, the through-substrate via coupled to a second one of the second plurality of conductive contacts of the microelectronic component.

17. The microelectronic assembly of claim 14, the substrate further comprising a third layer between the first layer and the second layer, the third layer not comprising the dopant.

18. The microelectronic assembly of claim 14, further comprising a second microelectronic component comprising a third plurality of conductive contacts at a first face of the second microelectronic component, wherein one of the third plurality of conductive contacts of the second microelectronic component is conductively coupled to a second one of the first plurality of conductive contacts of the bridge component.

19. An assembly comprising:
a substrate comprising a first dielectric layer and a second dielectric layer over the first dielectric layer, the first dielectric layer comprising a dopant, and the first dielectric layer having a plurality of conductive structures formed therein;
a first die having a first face and a second face, the first face of the first die having contacts electrically coupled to the plurality of conductive structures in the first dielectric layer;
a second die electrically coupled to the first die at the second face of the first die; and
a third die electrically coupled to the first die at the second face of the first die.

20. The assembly of claim 19, wherein a first portion of the second die is over the first die, and a second portion of the second die is not over the first die.
